(19) United States
(12) Patent Application Publication
(10) Pub. No.: US 2025/0385098 A1
(43) Pub. Date: Dec. 18, 2025

(54) SEMICONDUCTOR DEVICE WITH METAL GATE STRUCTURE AND METHOD OF FORMING SAME

(71) Applicant: Taiwan Semiconductor Manufacturing Company, Ltd., Hsin-Chu (TW)

(72) Inventors: Yu-Jiun PENG, Hsinchu (TW); Hsiu-Hao TSAO, Taichung (TW); Shao-Hua HSU, Taitung City (TW); Chia-I LIN, Taipei City (TW); Kai-Min CHIEN, New Taipei City (TW); Yuan-Cheng HU, Taichung City (TW); Shu-Han CHEN, Hsinchu City (TW); Min-Chia LEE, Hsinchu City (TW); Ming-Chang WEN, Kaohsiung City (TW)

(21) Appl. No.: 18/949,741

(22) Filed: Nov. 15, 2024

Related U.S. Application Data
(60) Provisional application No. 63/658,911, filed on Jun. 12, 2024.

(51) Int. Cl. H01L 21/3105; H01L 21/283; H01L 29/06; H01L 29/417; H01L 29/423; H01L 29/66; H01L 29/775; H01L 29/786

(52) U.S. Cl. CPC H01L 21/3105; H01L 21/283; H10D 30/014; H10D 64/017; H10D 30/43; H10D 30/6735; H10D 30/6757; H10D 62/121; H10D 64/258

(57) ABSTRACT

A method includes forming a fin protruding from a substrate, forming a dummy gate stack across the fin, the dummy gate stack including a dummy gate dielectric layer, a dummy gate electrode over the dummy gate dielectric layer, and an oxide layer disposed on sidewalls of the dummy gate electrode, forming gate spacers on sidewalls of the dummy gate stack, removing the dummy gate electrode, recessing the oxide layer, passivating a surface portion of the gate spacers to form a passivation layer above the oxide layer, removing the passivation layer, the oxide layer, and the dummy gate dielectric layer to form a gate trench, depositing a metal gate stack in the gate trench, and recessing the metal gate stack. A top portion of the passivation layer is wider than a bottom portion of the passivation layer.

### PRIORITY DATA

This application claims priority to U.S. Provisional Patent Application No. 63/658,911 filed on Jun. 12, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

As technology nodes shrink, one advancement in some IC designs has been the replacement of polysilicon gates with metal gates to improve device performance at decreased feature sizes. One process of forming a metal gate is termed a “replacement gate” or “gate-last” process, in which the metal gate is fabricated “last,” allowing for a reduced number of subsequent processes. A “replacement gate” process typically includes forming a dummy gate to reserve a space for a metal gate and subsequently removing the dummy gate to form a gate trench for a metal gate gap-filling process. In the metal gate gap-filling process, various metal layers, such as work function metal layers and metal fill layers, are sequentially deposited in the gate trench. However, there are challenges to implementing such IC fabrication processes, especially with scaled-down IC features in advanced process nodes. One challenge is due to the narrow opening of the gate trench, such that voids (also referred to as seams due to their generally high aspect ratio) may be trapped in the gate trench during the metal gate gap-filling process. These voids may introduce punch-through defects during a metal gate etch-back process. The narrow opening of the gate trench may also cause difficulty to remove temporary gap-filling layers from the gate trench. Therefore, while current methods have been satisfactory in many respects, as transistor dimensions continue to scale down to sub-10 nm technology nodes, further improvements in metal gate formation are still needed.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method of forming a semiconductor device, according to various aspects of the present disclosure.

FIGS. 2, 3, 4, 5, 6, 7, 8, 9, 10, 11, and 12 illustrate perspective views of a semiconductor structure during fabrication stages of the method in FIG. 1, according to various aspects of the present disclosure.

FIGS. 13, 14, 15, 16, 17, 18, 19, 20, 21, 22, 23, 24, 25, 26, 27A, 27B, 27C, 28, 29, 30A, 30B, 30C, 31, 32, 33A, 33B, 33C, 34, 35, 36A, 36B, and 36C illustrate cross-sectional views of a semiconductor structure during fabrication stages of the method in FIG. 1, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

The present disclosure is generally related to a semiconductor device and methods of forming the same. More particularly, embodiments of the present disclosure provide a metal gate formation process, which may be employed in a variety of device types.

Some device types are related to, but not otherwise limited to, multi-gate devices. Multi-gate devices have been introduced in an effort to improve gate control by increasing gate-channel coupling, reduce OFF-state current, and reduce short-channel effects (SCEs). One such multi-gate device that has been introduced is the fin-like field-effect transistor (FinFET). The FinFET gets its name from the fin-like structure which extends from a substrate on which it is formed, and which is used to form the FET channel. Another multi-gate device, introduced in part to address performance challenges associated with the FinFET, is the gate-all-around (GAA) transistor. The GAA transistor gets its name from the gate structure which can extend around the channel region (e.g., a stack of nanosheets) providing access to the channel on four sides. The GAA transistor is compatible with conventional complementary metal-oxide-semiconductor (CMOS) processes and its structure allows it to be aggressively scaled while maintaining gate control and mitigating SCEs. The following disclosure will continue with one or more GAA examples to illustrate various embodiments of the present disclosure. It is understood, however, that the application should not be limited to a particular type of device, except as specifically claimed. For example, aspects of the present disclosure may also apply to implementation based on FinFETs or planar FETs.

As transistor dimensions are continually scaled down to sub-10 nm technology nodes and below, the gate trench defined by a dummy gate over a fin-like structure-such as a fin for a FinFET device or a patterned stack of channel layers interleaved with sacrificial layers for a GAA device—may exhibit a high aspect ratio and/or a necking profile. For simplicity, the terms “fin-like structure” and “fin” are used interchangeably throughout this description.

When various metal layers are sequentially deposited in the gate trench, voids (or seams) may be easily trapped in the gate trench due to the high aspect ratio and/or the necking profile of the gate trench. During the metal gate etch-back process, etchants may leak into the seams and cause uneven etching of the metal layers, resulting in punch-through defects and poor growth of gate metal cap. The high aspect ratio and/or the necking profile of the gate trench also makes the removal of temporary layers (e.g., sacrificial layers in the fin and/or gap-filling layers during the formation of work function metal (WFM) layers) quite challenging. In accordance with some embodiments of the present disclosure, during the removal of the dummy gate to form a gate trench, the gate trench profile is re-engineered to have a wider opening. A gradient passivation process (e.g., a gradient oxidation process) is performed to passivate a surface portion of the gate spacer facing the gate trench. The passivated surface portion has a larger thickness near the opening of the gate trench and a smaller thickness near the bottom of the gate trench due to the gradient passivation process. The passivated surface portion of the gate spacer is subsequently removed in a selective etch process. The removal of the passivated surface portion enlarges the opening of the gate trench. The enlarged opening facilitates subsequent deposition of WFM layer and metal fill layers in filling the gate trench without trapping voids (or seams). The proposed metal gate formation process improves uniformity and integrity of gate metal layers and thus leads to better performance of transistors.

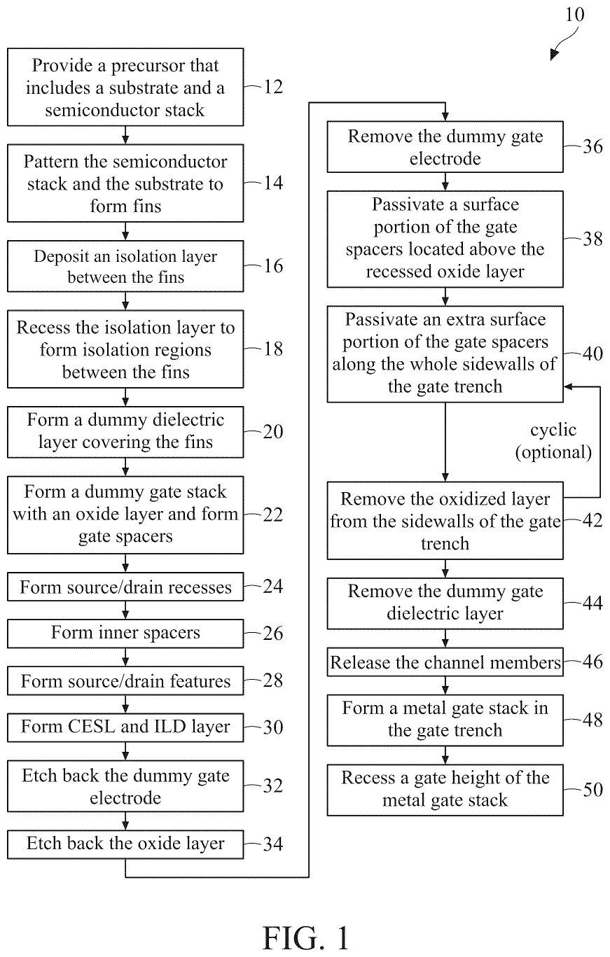

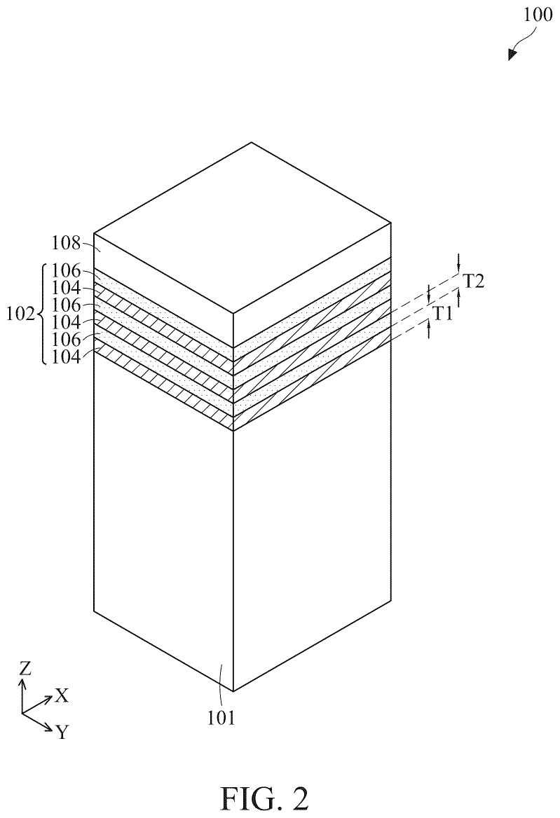

FIG. 1 illustrates a flow chart of a method 10 for forming a semiconductor device according to the present disclosure. The method 10 is an example, and is not intended to limit the present disclosure beyond what is explicitly recited in the claims. Additional operations can be provided before, during, and after the method 10, and some operations described can be replaced, eliminated, or relocated for additional embodiments of the method. The method 10 is described below in conjunction with FIGS. 2-36C, which illustrate perspective views and cross-sectional views of a semiconductor device 100 during various fabrication steps according to some embodiments of the method 10. The semiconductor device 100 may be an intermediate device fabricated during processing of an integrated circuit (IC), or a portion thereof, that may comprise static random access memory (SRAM) and/or logic circuits, passive components such as resistors, capacitors, and inductors, and active components such as p-type FETs (pFETs), n-type FETs (nFETs), metal-oxide semiconductor field effect transistors (MOSFET), and complementary metal-oxide semiconductor (CMOS) transistors, bipolar transistors, high voltage transistors, high frequency transistors, other memory cells, and combinations thereof. Furthermore, the various features including transistors, gate stacks, active regions, isolation structures, and other features in various embodiments of the present disclosure are provided for simplification and ease of understanding and do not necessarily limit the embodiments to any types of devices, any number of devices, any number of regions, or any configuration of structures or regions.

Referring to FIGS. 1 and 2, at operation 12, the method 10 (FIG. 1) provides (or receives) a precursor of the semiconductor device 100. For the convenience of discussion, the precursor of the semiconductor device 100 is also referred to as the device 100. The device 100 may include a substrate 101 and various features formed therein or thereon. In some embodiments, the substrate 101 includes a crystalline silicon substrate (e.g., wafer). The substrate 101 may include various doped regions (e.g., p-type well and/or n-type well) depending on design requirements. In some embodiments, the doped regions may be doped with p-type or n-type dopants. For example, the doped regions may be doped with p-type dopants, such as boron or BF₂, n-type dopants, such as phosphorus or arsenic, and/or combinations thereof. The doped regions may be configured for n-type transistors, or alternatively, configured for p-type transistors. In some embodiments, an anti-punch-through (APT) implantation is performed on a top portion of the substrate 101 to form an APT region. The conductivity type of the dopants implanted in the APT region is the same as that of the doped regions (or wells). The APT region may extend under the subsequently formed source/drain regions, and are used to reduce the leakage from the source/drain regions to substrate 101. Source/drain region(s) may refer to a source or a drain, individually or collectively dependent upon the context. For clarity, the doped regions and the APT region are not illustrated in FIG. 1 and subsequent drawings. In some alternative embodiments, the substrate 101 includes an element semiconductor such as silicon or germanium, a compound semiconductor such as silicon carbide, gallium arsenic, gallium phosphide, indium phosphide, indium arsenide and indium antimonide, an alloy semiconductor such as SiGe, GaAsP, AlInAs, AlGaAs, GaInAs, GaInP and GaInAsP or combinations thereof.

The device 100 includes a semiconductor stack 102 formed on the substrate 101. The semiconductor stack 102 may include a plurality of first layers 104 and a plurality of second layers 106 stacked alternately in a Z-direction. Although only three first layers 104 and three second layers 106 are illustrated in FIG. 2, the embodiments of the present disclosure are not limited thereto. In other embodiments, the number of the first layers 104 and the second layers 106 are adjusted by the need, such as one, two, four, or more first layers 104 and second layers 106.

In some embodiments, the first layers 104 and the second layers 106 include different materials. For example, the first layers 104 are SiGe layers having a germanium atomic percentage in the range between about 15% and 40%, and the second layers 106 are Si layers free from germanium. However, the embodiment of the disclosure is not limited thereto, in other embodiments, the first layers 104 and the second layers 106 have materials with different etching selectivity. In some embodiments, the first layers 104 and the second layers 106 are formed by an epitaxial growth process, such as a molecular beam epitaxy (MBE) process, a metalorganic chemical vapor deposition (MOCVD) process, or the like. In the case, the first layers 104 are epitaxial SiGe layers, and the second layers 106 are epitaxial Si layers. In some alternative embodiments, the first layers 104 and the second layers 106 are formed by a suitable deposition, such as chemical vapor deposition (CVD), atomic layer deposition (ALD), or the like. In the case, the first layers 104 are poly-SiGe layers, and the second layers 106 are poly-Si layers.

The first layers 104 and the second layers 106 may have the same or different thicknesses. In some embodiments, the first layers 104 have the same thickness T1 and the second layers 106 have the same thickness T2. In some embodiments, the thickness T1 ranges from about 5 nm to about 20 nm and the second thickness T2 ranges from about 5 nm to about 20 nm. Alternatively, the top to bottom first layers 104 may have different thicknesses, and the top to bottom second layers 106 may have different thicknesses.

The device 100 also includes a mask layer 108 formed on the semiconductor stack 102. The mask layer 108 may include a single-layered structure, a two-layered structure, or a multi-layered structure. For example, the mask layer 108 includes a silicon oxide (SiO) layer and a silicon nitride (SiN) layer on the SiO layer. In some embodiments, the mask layer 108 is formed by CVD, ALD, or the like.

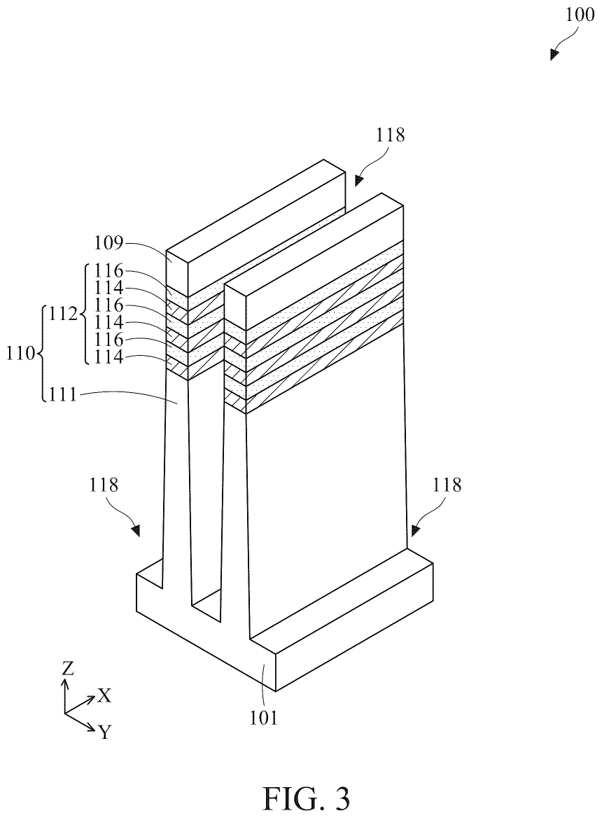

Referring to FIGS. 1 and 3, at operation 14, the method 10 patterns the mask layer 108, the semiconductor stack 102 of the first and second layers 104, 106, and a top portion of the substrate 101 to form fins 110. In some embodiments, the mask layer 108 is patterned to form a plurality of mask strips 109. The semiconductor stack 102 and the substrate 101 are then patterned by using the mask strips 109 as a mask, so as to form a plurality of trenches 118. In the case, a plurality of fin bases 111 and a plurality of stacks of semiconductor strips 112 on the fin bases 111 are formed between the trenches 118. The trenches 118 extend into the substrate 101, and have lengthwise directions parallel to each other. Herein, the stacks of semiconductor strips 112 are referred to as nanosheet stacks 112 and the combination of the fin bases 111 and the nanosheet stacks 112 thereon are referred to as fins 110. As shown in FIG. 3, the nanosheet stack 112 includes a plurality of first nanosheets 114 and a plurality of second nanosheets 116 stacked alternately along a Z-direction and extending along a Y direction.

In some embodiments, the fins 110 may be patterned by any suitable method. For example, the fins may be patterned using one or more photolithography processes, including double-patterning or multi-patterning processes. The double-patterning or the multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 110.

Although only two fins 110 are illustrated in FIG. 3, the embodiments of the present disclosure are not limited thereto. In other embodiments, the number of the fins 110 may be adjusted by the need, such as one fin, three fins, four fins, or more fins. In addition, the mask strips 109 illustrated in FIG. 3 have flat top surfaces. However, the embodiments of the present disclosure are not limited thereto. In other embodiments, the mask strips 109 may have dome top surfaces due to the high aspect ratio etching.

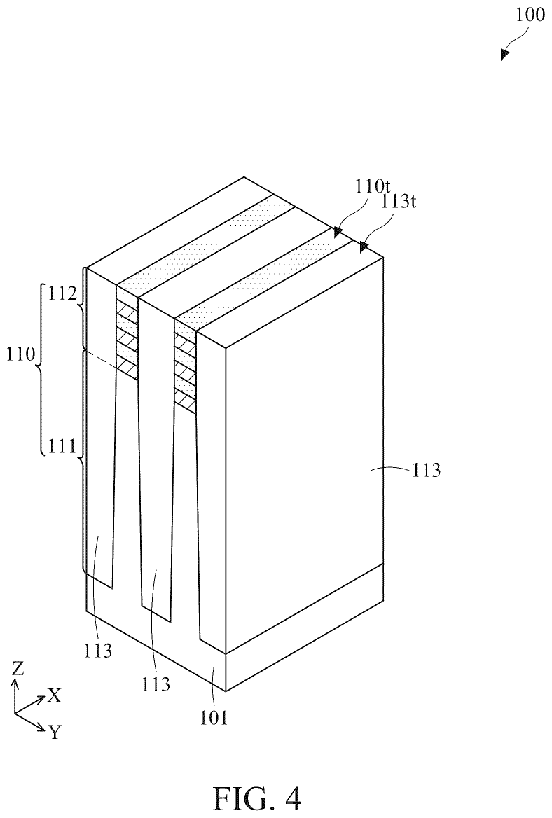

Referring to FIGS. 1 and 4, at operation 16, the method 10 forms insulating layer 113 in the trenches 118. In some embodiments, an insulating material is formed on the substrate 101 to cover the fins 110 and to fill up the trenches 118. In addition to the fins 110, the insulating material further covers the mask strips 109. The insulating material may include silicon oxide, silicon nitride, silicon oxynitride, a spin-on dielectric material, or a low-k dielectric material. Herein, the low-k dielectric materials are generally dielectric materials having a dielectric constant lower than 5.0, such as a dielectric constant lower than that of silicon oxide (about 3.9). The insulating material may be formed by flowable chemical vapor deposition (FCVD), high-density-plasma chemical vapor deposition (HDP-CVD), sub-atmospheric CVD (SACVD), or spin on. A planarization process may be performed, to remove a portion of the insulating material and the mask strips 109 until the fins 110 are exposed. In the case, as shown in FIG. 4, top surfaces 110t of the fins 110 are substantially coplanar with a top surface 113t of the planarized insulating layer 113. In some embodiments, the planarization process includes a chemical mechanical polish (CMP), an etching back process, a combination thereof, or the like.

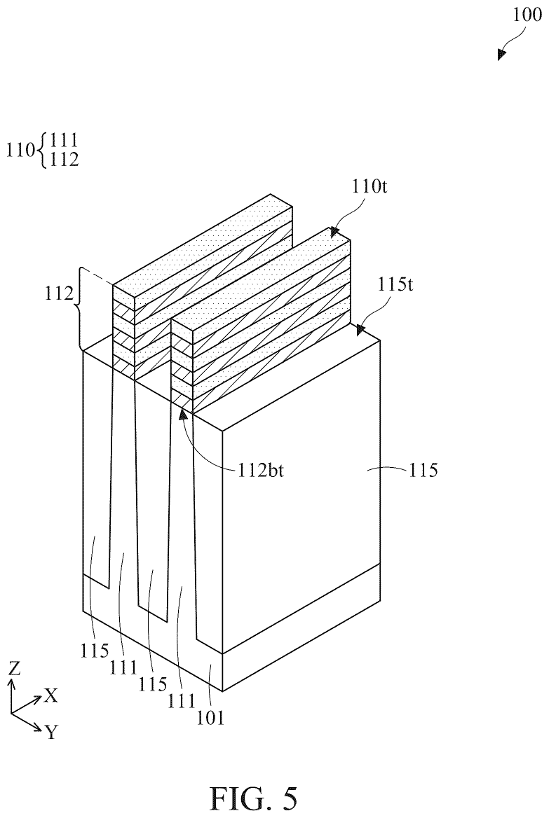

Referring to FIGS. 1 and 5, at operation 18, the method 10 recesses the insulating layer 113 to form a plurality of isolation regions 115. After recessing the insulating layers 113, the fins 110 protrude from top surfaces 115t of the isolation regions 115. That is, the top surfaces 115t of the isolation regions 115 may be lower than the top surfaces 110t of the fins 110. In some embodiments, the nanosheet stacks 112 are exposed by the isolation regions 115. That is, the top surfaces 115t of the isolation regions 115 may be substantially coplanar with or lower than bottom surfaces 112bt of the nanosheet stacks 112. Further, the top surfaces 115t of the isolation regions 115 may have a flat surface as illustrated, a convex surface, a concave surface (such as dishing), or a combination thereof. In some embodiments, the insulating layers 113 are recessed by using an appropriate etching process, such as a wet etching process with hydrofluoric acid (HF), a dry etching process, or a combination thereof. In some embodiments, a height difference between the top surfaces 110t of the fins 110 and the top surfaces 115t of the isolation regions 115 ranges from about 30 nm to about 100 nm. In some embodiments, the isolation regions 115 may be shallow trench isolation (STI) regions, deep trench isolation (DTI) regions, or the like.

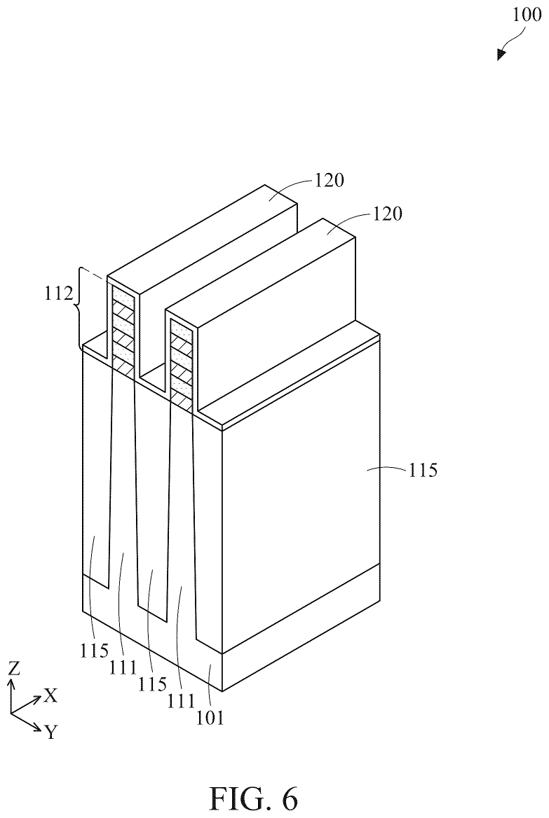

Referring to FIGS. 1 and 6, at operation 20, the method 10 forms a dummy dielectric layer 120 on the substrate 101. In some embodiments, the dummy dielectric layer 120 conformally covers the surfaces of the nanosheet stacks 112 and the top surfaces 115t of the isolation regions 115. In some embodiments, the dummy dielectric layer 120 includes silicon oxide, silicon nitride, silicon oxynitride, or the like, and may be formed by CVD, ALD or the like. A thickness of the dummy dielectric layer 120 may range from about 1 nm to about 5 nm, in some embodiments. The dummy dielectric layer 120 and the isolation regions 115 may have the same or different dielectric materials.

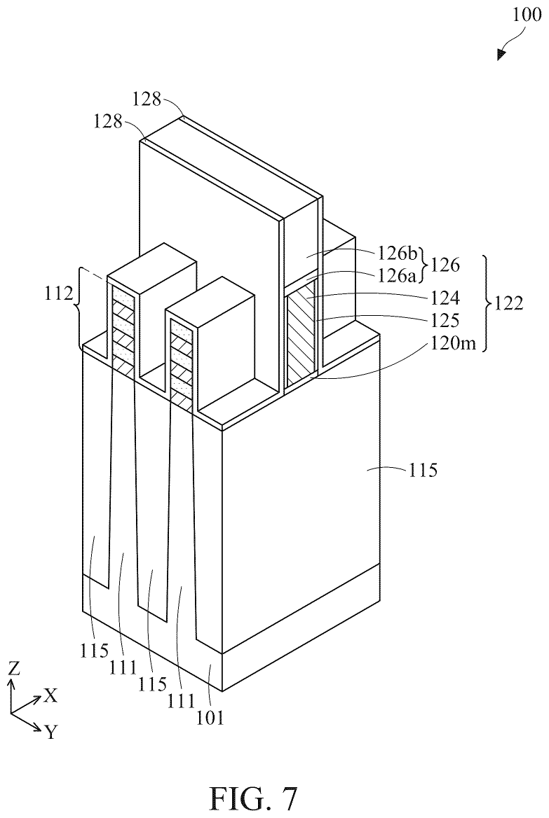

Referring to FIGS. 1 and 7, at operation 22, the method 10 forms a dummy gate stack 122 is formed over portions of the nanosheet stacks 112 and portion of the isolation regions 115. The dummy gate stack 122 may extend along a Y-direction perpendicular to the extending direction of the nanosheet stacks 112. That is, the dummy gate stack 122 may be formed across the nanosheet stacks 112. Specifically, the dummy gate stack 122 may include dummy gate electrode 124 and a portion of the dummy dielectric layer 120 covered by the dummy gate electrode 124. Patterning of the dummy gate stack 122 may remove uncovered portions of the dummy dielectric layer 120. Herein, the portion of the dummy dielectric layer 120 covered by the dummy gate electrode 124 is referred to as dummy gate dielectric layer 120m. In some embodiments, the dummy gate electrode 124 includes a silicon-containing material, such as polysilicon, amorphous silicon, or a combination thereof. The dummy gate electrode 124 may be formed by using a suitable process, such as ALD, CVD, PVD, plating, or combinations thereof. Although the dummy gate electrode 124 illustrated in FIG. 7 is a single-layered structure, the embodiments of the present disclosure are not limited thereto. In other embodiments, the dummy gate electrode 124 may be a multi-layered structure. The dummy gate stack 122 may also include hard mask layer 126 over dummy gate electrode 124. In some embodiments, the hard mask layer 126 includes a single-layered structure, a two-layered structure, a multi-layered structure. For example, as in FIG. 7, the hard mask layer 126 includes a silicon oxide layer 126a and a silicon nitride layer 126b disposed over the silicon oxide layer 126a.

While not explicitly shown, after the dummy gate stack 122 is formed, method 10 may include a cleaning process to clean surfaces of the dummy gate stack 122. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide, a sulfuric peroxide mixture, and/or hydrofluoric acid for oxide removal. The dry clean process may include helium (He) and hydrogen (H₂) treatment. The cleaning process may passivate sidewall surfaces of the dummy gate electrode 124. In some embodiments, the sidewall surfaces of the dummy gate electrode 124 is oxidized to form an oxide layer 125. For example, when the dummy gate electrode 124 is formed of polysilicon, the oxide layer 125 may be a thin film of silicon oxide. In some embodiments, the cleaning process is skipped, while the sidewall surfaces of the dummy gate electrode 124 may still be oxidized due to being exposed in an oxygen-containing environment. Since the oxide layer 125 is formed on the sidewalls of the dummy gate stack 122, the oxide layer 125 is also referred to as the gate sidewall oxide layer 125; since the oxide layer 125 is a byproduct of the cleaning process or a natural oxidization process, the oxide layer 125 is also referred to as a native oxide layer 125. A thickness of the oxide layer 125 may range from about 0.5 nm to about 3 nm, which is thinner than the dummy gate dielectric layer 120m. A density of the oxide layer 125 may also be smaller than the dummy gate dielectric layer 120m.

Still referring to FIG. 7, gate spacers 128 are also formed on sidewalls of the dummy gate stack 122. Similar to the dummy gate stack 122, the gate spacers 128 are formed across the nanosheet stacks 112. In some embodiments, the gate spacers 128 are formed of one or more dielectric materials, such as SiCN, SiC, SiOCN, SiOC, SiON, or a combination thereof. In furtherance of some embodiments, the gate spacers 128 may comprise a low-k material having a k-value less than about 5.0, such as about 3.9 or even less. For example, in some embodiments the gate spacers 128 may include a porous dielectric material, an extreme low-k (ELK) dielectric material (e.g., SiCOH), and the like. The gate spacers 128 may or may not include air gaps (not illustrated) to further reduce its k-value. The low-k material of the gate spacers 128 is used to advantageously reduce parasitic capacitance between subsequently formed metal gate structure and source/drain contact(s) particularly in advanced node technologies where the metal gate structure and source/drain contact(s) are in close proximity. A thickness of the gate spacers 128 ranges from about 1 nm to about 10 nm in some embodiments. The gate spacers 128 may be a single-layered structure or a multi-layered structure. For example, the gate spacers 128 may include a first gate spacer layer and a second gate spacer layer disposed on the first gate spacer layer, which are formed of different dielectric materials. The dummy gate stack 122 and the gate spacers 128 cover middle portions of the nanosheet stacks 112 and reveal the opposite end portions not covered.

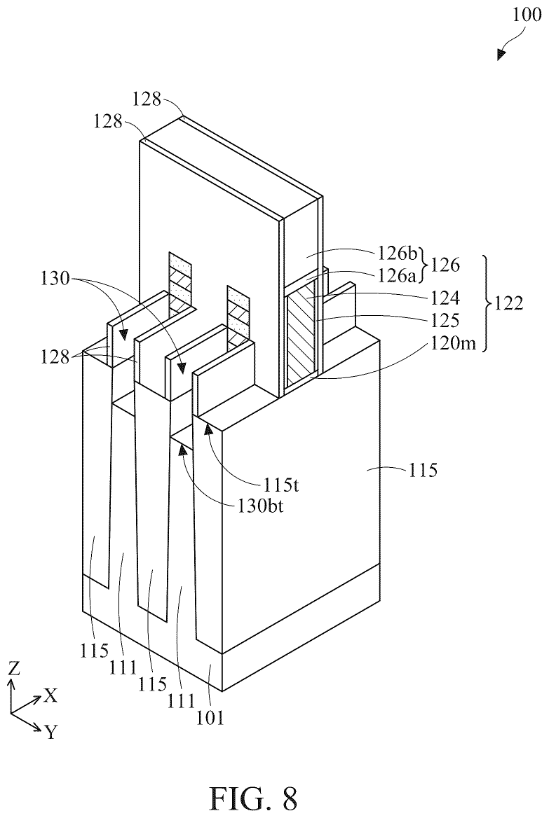

Referring to FIGS. 1 and 8, at operation 24, the method 10 recesses the end portions of the nanosheet stacks 112 to form recesses 130. Herein, the recesses 130 may be referred to as source/drain recesses 130. In some embodiments, the end portions of the nanosheet stacks 112 may be removed by an anisotropic etching process, an isotropic etching process, or a combination thereof. In some embodiments, the source/drain recesses 130 further extend into the fin bases 111 and are lower than the top surfaces 115t of the isolation regions 115. In other words, the end portions of the nanosheet stacks 112 are entirely removed and top portions of the fin bases 111 are further removed. In the case, as shown in FIG. 8, the bottom surfaces 130bt of the source/drain recesses 130 are lower than the top surfaces 115t of the isolation regions 115. In some embodiments, some horizontal portions of the gate spacers 128 are removed and other vertical portions of the gate spacers 128 may be left standing over and aligned to the edges of isolation regions 115, with the source/drain recesses 130 formed therebetween. The vertical portions of the gate spacers 128 cover sidewalls of the dummy gate stack 122 that includes the dummy gate dielectric layer 120m, the dummy gate electrode 124, and the hard mask layer 126.

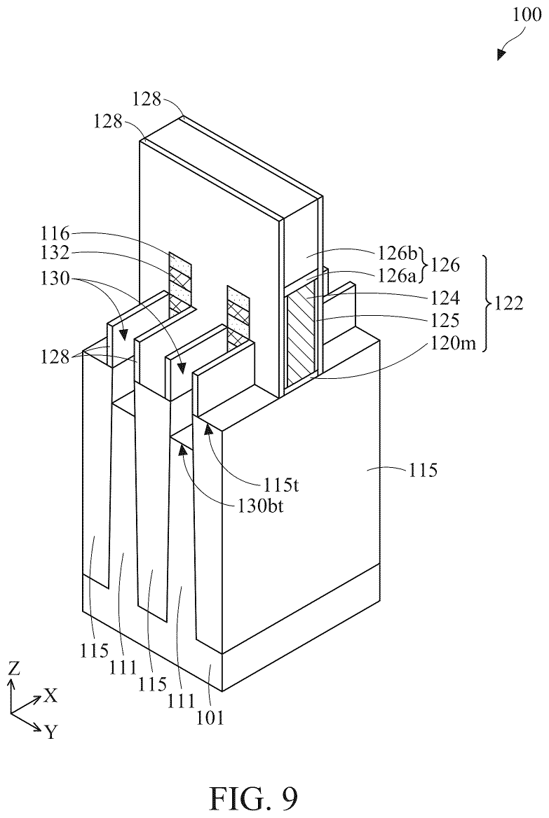

Referring to FIGS. 1 and 9, at operation 26, the method 10 forms inner spacers 132 at opposite end portions of the first nanosheets 114. In some embodiments, opposite end portions of the first nanosheets 114 as exposed in the source/drain recesses 130 are selectively and partially recessed to form inner spacer recesses (not shown), while the second nanosheets 116 are substantially unetched. In an embodiment where the second nanosheets 116 consist essentially of silicon (Si) and the first nanosheets 114 consist essentially of silicon germanium (SiGe), the selective and partial recess of the first nanosheets 114 may include a SiGe oxidation process followed by a SiGe oxide removal. The SiGe oxidation process may include use of ozone (O₃). In some other embodiments, the selective recess may be a selective isotropic etching process (e.g., a selective dry etching process or a selective wet etching process), and the extent at which the first nanosheets 114 are recessed is controlled by duration of the etching process. The selective dry etching process may include use of one or more fluorine-based etchants, such as fluorine gas or hydrofluorocarbons. The selective wet etching process may include a hydro fluoride (HF) or NH₄OH etchant. After the formation of the inner spacer recesses, an inner spacer material layer is deposited over the semiconductor device 100, including in the inner spacer recesses. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excess inner spacer material layer over the gate spacers 128 and sidewalls of the second nanosheets 116, thereby forming the inner spacers 132.

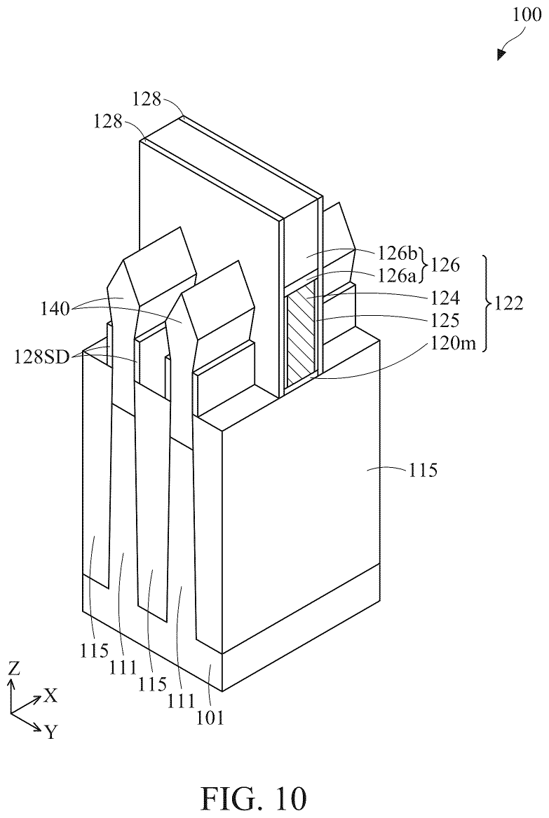

Referring to FIGS. 1 and 10, at operation 28, the method 10 epitaxially grows a strained material 140 (or a highly doped low resistance material) from the source/drain recesses 130. In some embodiments, the strained material 140 is used to strain or stress the second nanosheets 116 and the fin bases 111. Herein, the strained material 140 may be referred to as source/drain regions 140 or source/drain features 140. In the case, the strained material 140 includes a source disposed at one side of the dummy gate stack 122 and a drain disposed at another side of the dummy gate stack 122. The source covers an end of the fin bases 111, and the drain covers another end of the fin bases 111. The source/drain regions 140 are abutted and electrically connected to the second nanosheets 116, while the source/drain regions 140 are electrically isolated from the first nanosheets 114 by the inner spacers 132. In some embodiments, the source/drain regions 140 extends beyond the top surface of the nanosheet stacks 112. However, the embodiments of the present disclosure are not limited thereto, in other embodiments, the top surface of the source/drain regions 140 is substantially aligned with the top surface of the nanosheet stacks 112. The vertical portions of the gate spacers 128 that sandwich the source/drain regions 140 are also referred to as the source/drain sidewall spacers 128SD.

The source/drain regions 140 include any acceptable material, such as appropriate for p-type transistors or n-type transistors. For example, the source/drain regions 140 may include SiGe, SiGeB, Ge, GeSn, or the like, which is appropriate for p-type transistors. In some alternative embodiments, the source/drain regions 140 may include silicon, SiC, SiCP, SiP, or the like, which is appropriate for n-type transistors. In some embodiments, the source/drain regions 140 are formed by MOCVD, MBE, ALD, or the like. The source/drain regions 140 may comprise one or more semiconductor material layers. For example, the source/drain regions 140 may comprise a bottom semiconductor material layer, a middle semiconductor material layer, and a capping semiconductor material layer. Any number of semiconductor material layers may be used for the source/drain regions 140. Each of the semiconductor material layers may be formed of different semiconductor materials and may be doped to different dopant concentrations. In embodiments in which the source/drain regions 140 comprise three semiconductor material layers, the bottom semiconductor material layer may be deposited, the middle semiconductor material layer may be deposited over the bottom semiconductor material layer, and the capping semiconductor material layer may be deposited over the middle semiconductor material layer.

In some embodiments, the source/drain regions 140 are doped with a conductive dopant. For example, the source/drain regions 140, such as SiGe, may be epitaxial-grown with a p-type dopant for straining a p-type transistor. That is, the source/drain regions 140 are doped with the p-type dopant to be the source and the drain of the p-type transistor. The p-type dopant includes boron or BF₂, and the source/drain regions 140 may be epitaxial-grown by LPCVD process with in-situ doping. As discussed above, the source/drain regions 140 may be epitaxially-grown with multiple layers differed in dopant concentrations, such as a bottom layer of SiGe:B with Ge atomic percentage from about 45% to 55% and a boron concentration of about 1×10²¹/cm³ to about 2×10²¹/cm³, a middle layer of SiGe:B with Ge atomic percentage from about 45% to 60% and a boron concentration of about 8×10²⁰/cm³ to about 3×10²¹/cm³, and a capping layer of SiGe:B with Ge atomic percentage from about 25% to 45% and a boron concentration of about 1×10²⁰/cm³ to about 8×10²⁰/cm³. In some alternative embodiments, the source/drain regions 140, such as SiC, SiP, a combination of SiC/SiP, or SiCP is epitaxial-grown with an n-type dopant for straining an n-type transistor. That is, the source/drain regions 140 are doped with the n-type dopant to be the source and the drain of the n-type transistor. The n-type dopant includes arsenic and/or phosphorus, and the source/drain regions 140 may be epitaxial-grown by LPCVD process with in-situ doping. In some embodiments, the source/drain regions 140 are epitaxially-grown with multiple layers differed in dopant concentrations, such as a bottom layer of Si:P with a phosphorus concentration of about 1×10²¹/cm³ to about 2×10²¹/cm³, a middle layer of Si:P with a phosphorus concentration of about 1×10²¹/cm³ to about 4×10²¹/cm³, and a capping layer of Si:As with an arsenic concentration of about 1×10²⁰/cm³ to about 1×10²¹/cm³.

As a result of the epitaxial-grown process used to form the source/drain regions 140, the cross section of the source/drain regions 140 may have a diamond or pentagonal shape. However, the embodiments of the present disclosure are not limited thereto. In other embodiments, the cross section of the source/drain regions 140 also have a hexagonal shape, a pillar shape, or a bar shape. In some embodiments, as shown in FIG. 10, adjacent source/drain regions 140 are separated from each other after the epitaxial-grown process is completed. Alternatively, adjacent source/drain regions 140 may be merged.

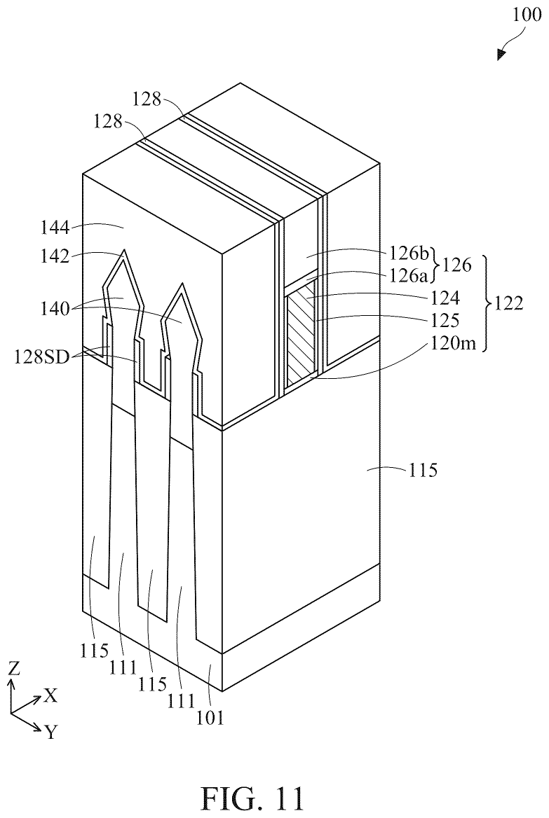

Referring to FIGS. 1 and 11, at operation 30, the method 10 forms an interlayer dielectric (ILD) layer 144 over the device 100. A contact etch stop layer (CESL) 142 may also be formed between the source/drain regions 140 and the ILD layer 144. In some embodiments, the CESL 142 conformally covers the source/drain regions 140 and the sidewalls of the outer sidewalls of the gate spacers 128. The CESL 142 may include silicon nitride, silicon oxynitride, silicon nitride with oxygen (O) or carbon (C) elements, and/or other materials; and may be formed by CVD, PVD (physical vapor deposition), ALD, or other suitable methods. The ILD layer 144 includes silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), SiOCN, SiOC, SiC, polyimide, and/or a combination thereof. In some other embodiments, the ILD layer 144 includes low-k dielectric materials. In alternative embodiments, the ILD layer 144 include one or more dielectric materials and/or one or more dielectric layers. In some embodiments, the ILD layer 144 is formed to a suitable thickness by FCVD, CVD, HDPCVD, SACVD, spin-on, sputtering, or other suitable methods. After the deposition of the ILD layer 144, the device 100 may be planarized by a planarization process to remove the hard mask layer 126 and expose the dummy gate electrode 124. For example, the planarization process may include a chemical mechanical planarization (CMP) process.

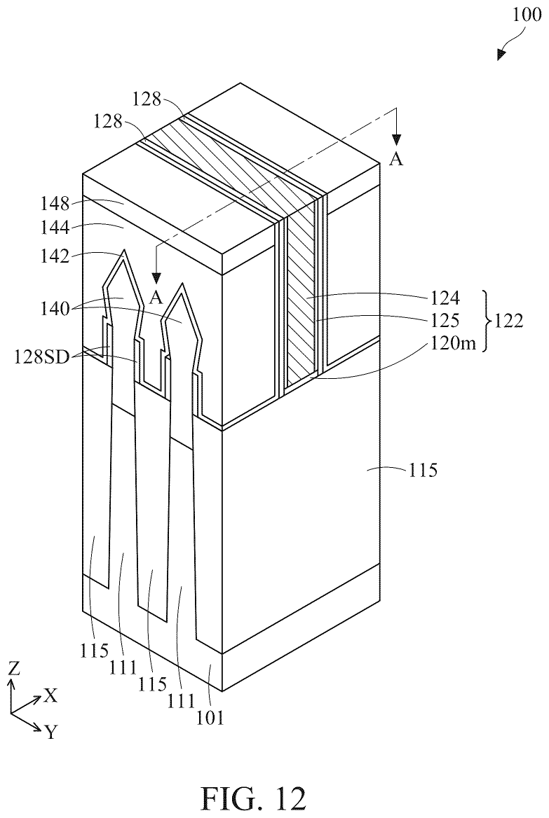

As shown in FIG. 12, in order to protect the ILD layer 144 from being damaged during the subsequent dummy gate stack removal step, the ILD layer 144 is selectively recessed to form a top recess and a capping layer 148 is formed over the top recess. The capping layer 148 is formed of a different material than the ILD layer 144. In some embodiments, the capping layer 148 may include silicon nitride, silicon carbonitride, silicon carbide, or silicon oxycarbonitride. In one embodiment, the capping layer 148 may include silicon nitride. Another planarization process, such as a CMP process, is performed to remove excess capping layer 148 and to expose the dummy gate electrode 124. After the planarization, top surfaces of the capping layer 148, the CESL 142, the gate spacers 128, the oxide layer 125, and the dummy gate electrode 124 are substantially coplanar.

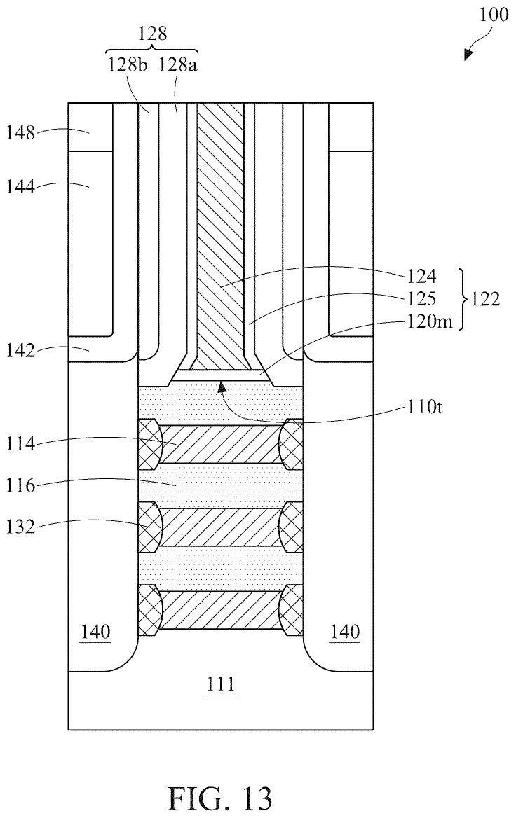

FIG. 13 shows a fragmentary cross-sectional view of the device 100 at the conclusion of operation 30 along the A-A line in FIG. 12, which cuts along a lengthwise direction of the first nanosheets 114 and the second nanosheets 116. In the depicted embodiment as shown in FIG. 13, the gate spacers 128 includes a first gate spacer layer 128a and a second gate spacer layer 128b. For example, the first gate spacer layer 128a may be formed on opposing sidewalls of the dummy gate stack 122, more particularly on the oxide layer 125. The second gate spacer layer 128b may be formed on the first gate spacer layer 128a. It should be understood that any number of gate spacer layers can be formed around the dummy gate stack 122 while remaining within the scope of the present disclosure. The first gate spacer layer 128a may be a low-k spacer and may be formed of a suitable dielectric material, such as silicon oxide, silicon oxycarbonitride, silicon oxycarbide, silicon oxynitride, or the like. The second gate spacer layer 128b may be formed of a nitride, such as silicon nitride, silicon oxynitride, silicon carbonitride, the like, or combinations thereof. Any suitable deposition method, such as thermal oxidation, chemical vapor deposition (CVD), or the like, may be used to form the first gate spacer layer 128a and the second gate spacer layer 128b. In accordance with various embodiments, the first gate spacer layer 128a and the second gate spacer layer 128b are formed of different dielectric materials. The oxide layer 125 is stacked between the first gate spacer layer 128a and the dummy gate electrode 124. Since the oxide layer 125 is a native oxide layer, its thickness and density are both smaller than those of the dummy gate dielectric layer 120m.

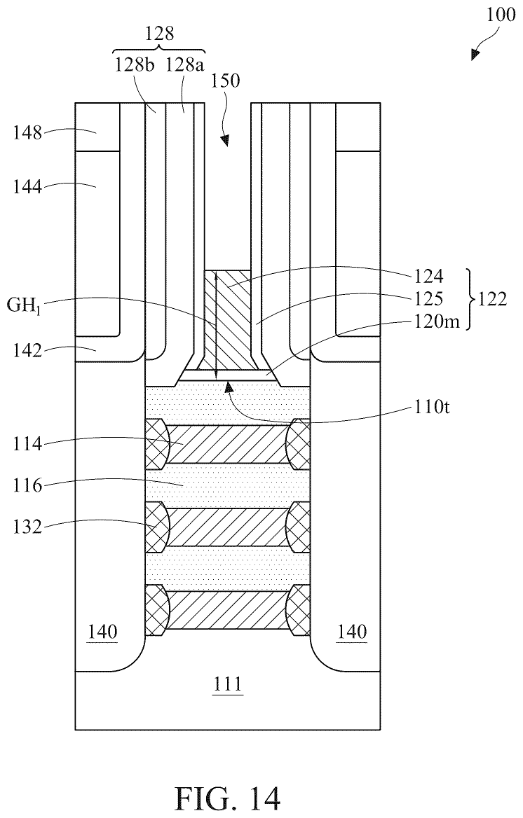

Also as illustrated in FIG. 13, the dummy gate stack 122 may exhibit a high aspect ratio. In a gate replacement process, the dummy gate stack 122 would be removed to form a gate trench. The gate trench would likely inherit the high aspect ratio from the dummy gate stack 122 or further develop a necking profile. Such a gate trench's profile would make subsequent removal of the first nanosheets 114, deposition and removal of gap-filling layers, and deposition of WFM layers, out of and/or into the gate trench, difficult. As discussed in further detail below, the gate trench's profile is reshaped to have its opening expanded, which may resemble a funnel shape. For clarity, subsequent steps of method 10 in reshaping the gate trench are described in conjunction with FIGS. 14-36C, which correspond to fragmentary cross-sectional views of the device 100 along the A-A line in FIG. 12.

Referring to FIGS. 1 and 14, at operation 32, the method 10 etches back the dummy gate electrode 124 to form a gate trench 150. In some embodiments, the etch back process may be a dry etch process that includes the use of a fluorine-containing gas, such as CF₄, SF₆, or NF₃. In furtherance of the embodiments, the dry etch process may be a plasma etch process with a mixture of NF₃ and H₂ as an etchant. The etchant is selected such that the oxide layer 125 is substantially intact and remains on opposing sidewall surfaces of the gate spacers 128. The remaining gate height (denoted as GH₁, measured from the recessed top surface of the dummy gate electrode 124 to the top surface 110t of the topmost one of the second nanosheets 116) is in a range from about 1 nm to about 20 nm in some embodiments. As discussed in detail blow, the gate height GH₁ defines a turning point of a funnel-like profile of a to-be-reshaped gate trench 150. The gate height GH₁ can be controlled by the etch time of the etch back process.

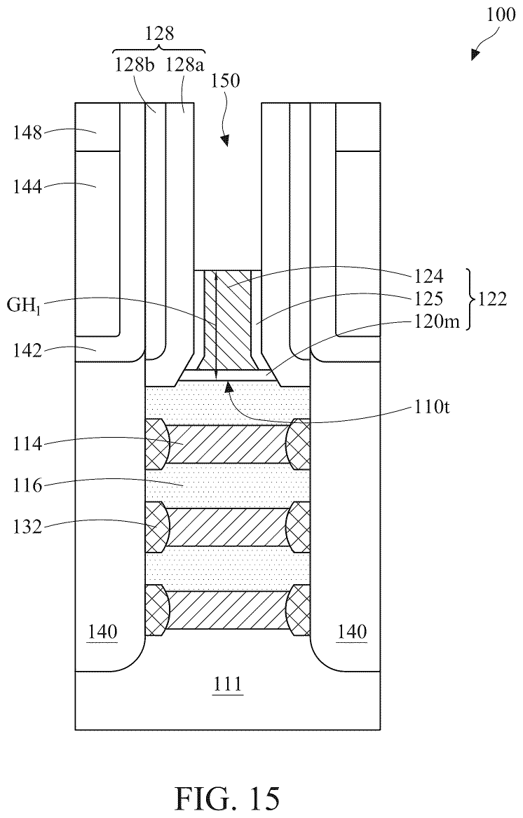

Referring to FIGS. 1 and 15, at operation 34, the method 10 etches back the oxide layer 125 to expose an upper portion of the sidewall surfaces of the first gate spacer layer 128a in the gate trench 150. In some embodiments, the etch back process may be a wet etch process that includes the use of a fluorine-containing liquid, such as a diluted solution of hydrofluoric acid (dHF). In furtherance of the embodiments, the wet etch process may use a dHF having a ratio of about 1:500. The etchant is selected such that the dummy gate electrode 124 is substantially intact. Due to the existence of the dummy gate electrode 124, it is the upper portion of the oxide layer 125 above the dummy gate electrode 124 that is removed.

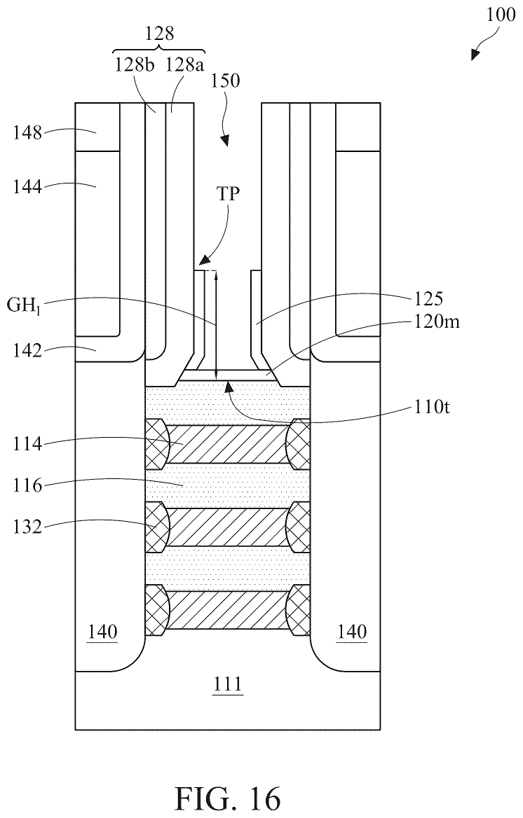

Referring to FIGS. 1 and 16, at operation 36, the method 10 completely removes the dummy gate electrode 124 in an etch back process and extends the gate trench 150 to the dummy gate dielectric layer 120m. In some embodiments, the etch back process may be a wet etch process that includes the use of a NH₄OH solution or a TMAH solution. The etchant is selected such that the oxide layer 125 and the dummy gate electrode 124 are substantially intact. The tip of the oxide layer 125 marks on the sidewall surfaces of the first gate spacer layer 128a a turning point (denoted as TP) of a funnel-like profile of a to-be-reshaped gate trench 150. The turning point TP is above the top surface 110t of the topmost one of the second nanosheets 116 for the defined gate height GH₁. The turning point TP is also referred to as a tuning point as the passivation treatment at operation 38 would be tuned to the exposed portion of the gate spacers 128 above the gate height GH₁.

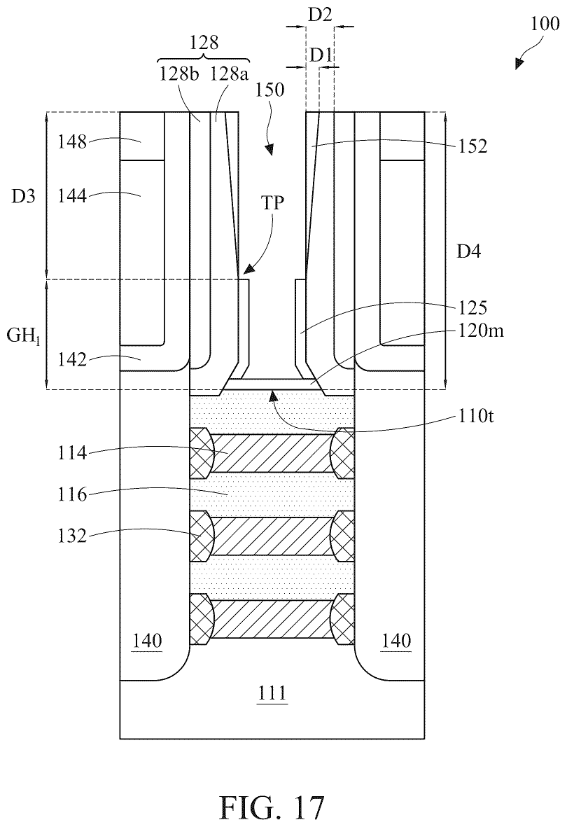

Referring to FIGS. 1 and 17, at operation 38, the method 10 forms a passivation layer 152 converted from a surface portion of the gate spacers 128, particularly from the first gate spacer layer 128a in the depicted embodiment. In some embodiments, the passivation process is an oxidation process, and the passivation layer 152 is an oxide layer formed by oxidizing the surface portion of the first gate spacer layer 128a using any suitable oxidation process such as an oxygen plasma process (a plasma treatment with O₂ and/or O₃ as oxidant species). After the passivation treatment, the oxygen concentration in the passivation layer 152 is higher than other portions of the gate spacers 128, and the carbon concentration and nitrogen concentration in the passivation layer 152 is lower than other portions of the gate spacers 128. The oxygen concentration between the passivation layer 152 and the oxide layer 125 may be different too. In one example, the oxygen concentration of the passivation layer 152 is higher than the oxide layer 125. In another example, the oxygen concentration of the passivation layer 152 is lower than the oxide layer 125. In some embodiments, the surface portion of the device 100 outside of the gate trench 150 (e.g., the gate spacers 128, the CESL 142, and the capping layer 148) may also be converted to a passivation layer. State differently, the passivation layer 152 may have horizontal portions extends on the top surface of the device 100 outside of the gate trench 150.

In an example process, the oxygen plasma process uses a gas mixture of an oxidant species (e.g., O₂ and/or O₃) and helium in a ratio between about 10:100 and about 50:100, under a radio frequency (RF) plasma power between about 1 KW and about 2 KW and an RF bias between about 10 W and about 150 W, under a process pressure between about 10 mTorr and about 30 mTorr, and under a thermal environment in a range between about 250° C. and about 450° C. In some embodiments, the passivation environment is controlled such that oxidant species (e.g., O₂ and/or O₃) has a higher concentration on the top surface of the device 100 and decreases in a gradient with distance away from the top surface of the device toward the bottom of the gate trench 150. The result is that nearer the top surface of the device 100, a thicker surface portion of the first gate spacer layer 128a is oxidized. The thickness of the passivation layer 152 decreases in a gradient as downward into the gate trench 150. Accordingly, the oxidation process is also referred to as a gradient oxidation process. Particularly, the remaining portion of the oxide layer 125 protects the covered lower portion of the first gate spacer layer 128a from the passivation process, such that the passivation layer 152 extends to the turning point TP and stops there. The gradient thickness of the passivation layer 152 defines a gate trench profile with a largest width on the top, a narrowed-down width in the middle, and a substantially constant width below the turning point TP.

In the depicted embodiment as shown in FIG. 17, the largest thickness (denoted as D1) of the passivation layer 152 measured at its top surface may range from about 0.1 nm to about 10 nm, and the thickness of the first gate spacer layer 128a (denoted as D2) may range from about 0.2 nm to about 15 nm. A difference between D2 and D1 (i.e., D2−D1) may range from about 0.1 nm to about 5 nm. A ratio between D1 and D2 (i.e., D1/D2) may be larger than about 0.1, which may be close to or even larger than 1. The ratio being larger than 1 means the passivation has been expanded into the second gate spacer layer 128b as well. A vertical distance from the turning point TP to the top surface of the device 100 (denoted as D3) may range from about 1 nm to about 99 nm, and a vertical distance from the top surface 110t to the top surface of the device 100 (denoted as D4, D4=D3+GH₁) may range from about 5 nm to about 100 nm. A ratio between D3 and D4 (i.e., D3/D4) may range from about 0.1 to about 0.99.

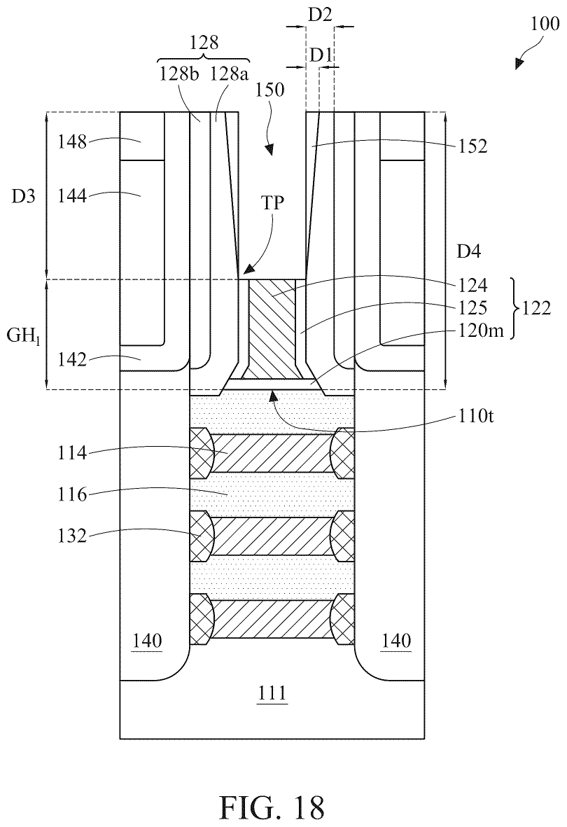

Alternatively, the method 10 may perform the removal of the dummy gate electrode 124 at operation 36 after the formation of the passivation layer 152 at operation 38, as depicted as an alternative embodiment in FIG. 18. After the passivation layer 152 is formed, a selective etching process removes the dummy gate electrode 124. After operation 36 and operation 38 are concluded in either sequence, the method 10 proceeds to operation 40.

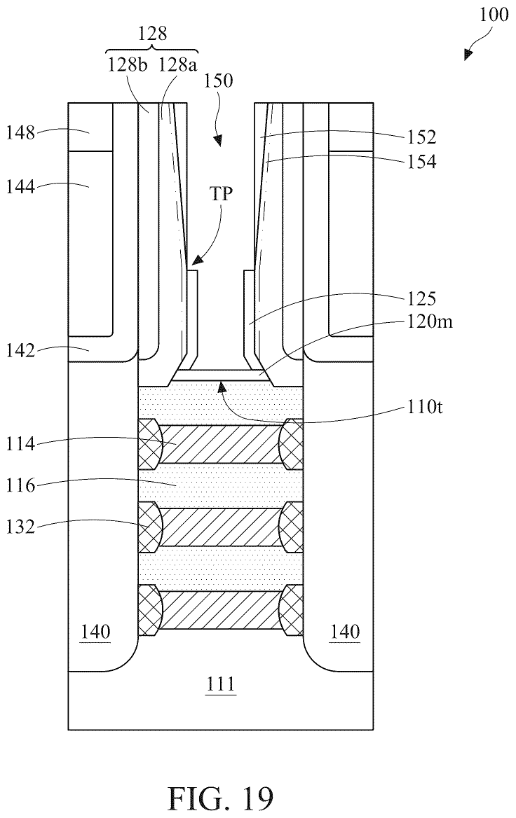

Referring to FIGS. 1 and 19, at operation 40, the method 10 subjects the gate spacers 128 to an isotropic passivation process to grow a thickness of the oxidized layer formed on the sidewall of the gate trench 150, which includes the passivation layer 152 and the oxide layer 125. In some embodiments, the isotropic passivation process is an anodic oxidation treatment that uses oxygen radicals without a plasma in a process chamber. The isotropic passivation process uniformly grows a thickness of the oxidize layer. In FIG. 19, the dotted line 154 marks an extra external portion of the gate spacers 128, particularly from the first gate spacer layer 128a, is converted to an oxidized layer. Since the extra converted portion has a substantially uniform thickness, the width of the gate trench 150 from top to bottom would be substantially uniformly expanded when the oxidize layer is removed from its sidewalls, yet the width difference of the gate trench 150's funnel-like profile is still defined by the shape of the passivation layer 152.

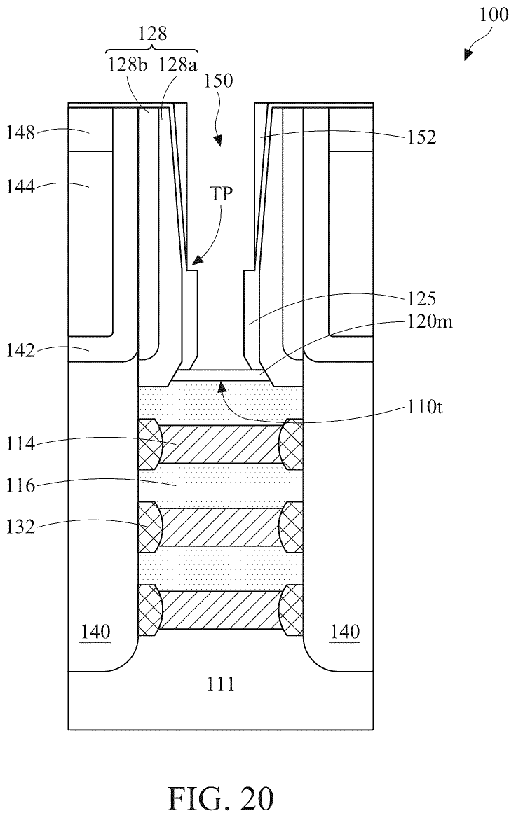

In an example process, the anodic oxidation treatment uses a gas mixture of an oxidant species (e.g., oxygen radicals and/or O₂), N₂, and H₂, with N₂H₂ as a carrier gas, under a process pressure between about 3 mTorr and about 3000 mTorr, and under a thermal environment in a range between about 100° C. and about 500° C. for a period between about 10 seconds and about 1000 seconds. Notably, the isotropic passivation process is tuned in a way that that it is not strong enough to penetrate the relatively harder and thicker dummy gate dielectric layer 120m, such that the thickness of the dummy gate dielectric layer 120m remains substantially unchanged during operation 40. After the anodic oxidation treatment, the oxygen concentration in the extra converted portion is higher than other untreated portions of the gate spacers 128, and the carbon concentration and nitrogen concentration in the extra converted portion is lower than other untreated portions of the gate spacers 128. The oxygen concentration between the extra converted portion and the oxide layer 125 may be different too. In one example, the oxygen concentration of the extra converted portion is higher than the oxide layer 125. In another example, the oxygen concentration of the extra converted portion is lower than the oxide layer 125. The resultant structure of device 100 after operation 40 is illustrated in FIG. 20. After the anodic oxidation treatment, the oxide layer 125 grows thicker, the passivation layer 152 also grows thicker at the same extent, yet the thickness of the dummy gate dielectric layer 120m remains substantially unchanged. The thickened passivation layer 152 and the thickened oxide layer 125 may be collectively referred to as one oxidized layer.

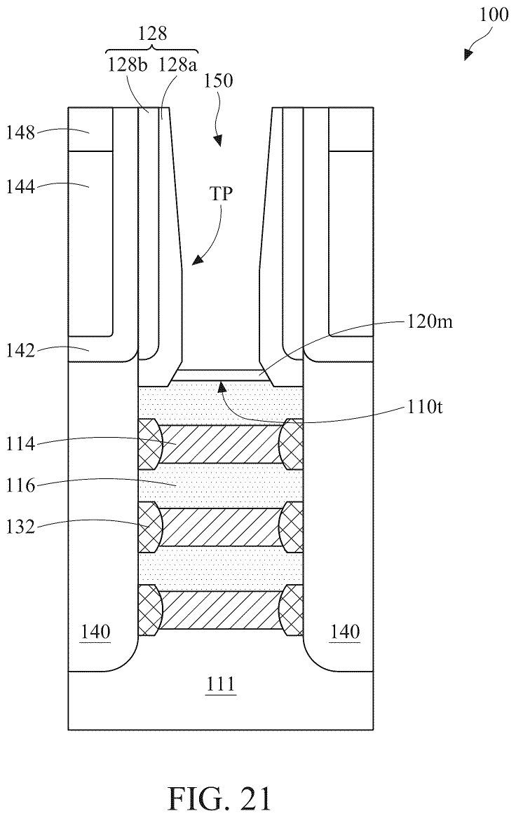

Referring to FIGS. 1 and 21, at operation 42, the method 10 removes the oxidized layer (including the passivation layer 152 and the oxide layer 125) from the sidewalls of the gate trench 150 to expose the first gate spacer layer 128a in the gate trench 150 in a trimming process. In some embodiments, the trimming process may be a wet etch process that includes the use of a fluorine-containing liquid, such as a diluted solution of hydrofluoric acid (dHF). In furtherance of the embodiments, the wet etch process may use a dHF having a ratio of about 1:500. The etchant is selected such that a substantial amount of the dummy gate dielectric layer 120m remains. Even though the dummy gate dielectric layer 120m also suffers from etch loss, due to the relatively higher density of the dummy gate dielectric layer 120m, the dummy gate dielectric layer 120m has a slower etch rate than the passivation layer 152 and the oxide layer 125. The resultant gate trench 150 has an expanded width with a funnel-like profile, particularly, a substantially uniform width between substantially vertical sidewalls under the turning point TP and a gradually expanding width between tapering sidewalls above the turning point TP.

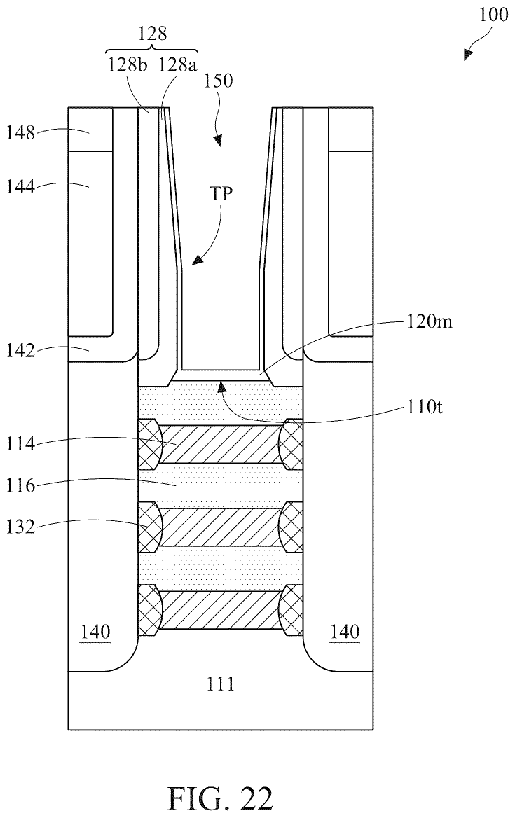

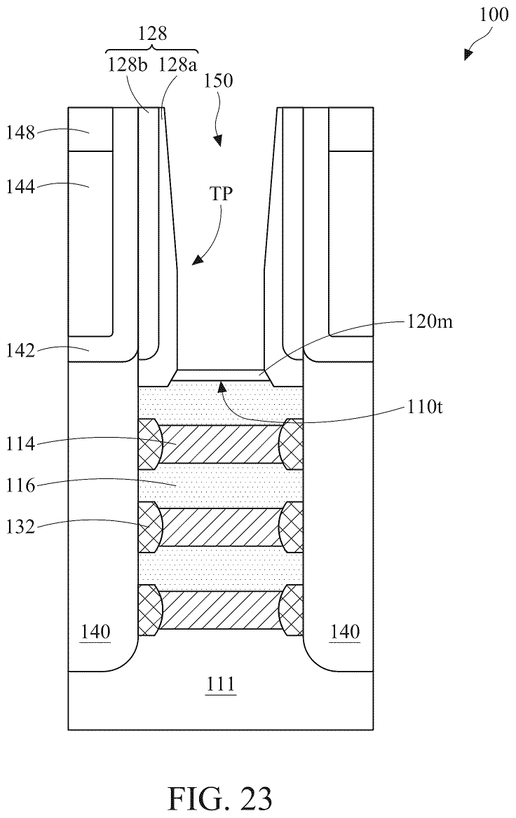

After the removal of the passivation layer 152 and the oxide layer 125, the method 10 may repeat operation 40 and operation 42 multiple times, such in a cyclic process, to passivate and remove external portions of the gate spacers 128 to further expand the gate trench 150 uniformly from top to bottom. The cyclic process may be repeated one, two, three, or more times until the gate trench 150 is expanded to a suitable width. During the cyclic process, the dummy gate dielectric layer 120m remains as a process stop layer in protecting the second nanosheets 116 underneath. FIGS. 22 and 23 illustrate after one cyclic process, an extra surface portion of the gate spacers 128 along the whole sidewalls of the gate trench 150 is oxidized and subsequently removed. Through the cyclic process, the opening of the gate trench 150 is expanded uniformly from top to bottom. The difference between the widths at the top and the bottom of the gate trench 150 remains the same, which is defined by the passivation layer 152 as discussed above. Notably, depending on the number of the cyclic process repeated, the expanded tapering sidewalls of the gate trench 150 may cut into the second gate spacer layer 128b and even the CESL 142, which will be illustrated later.

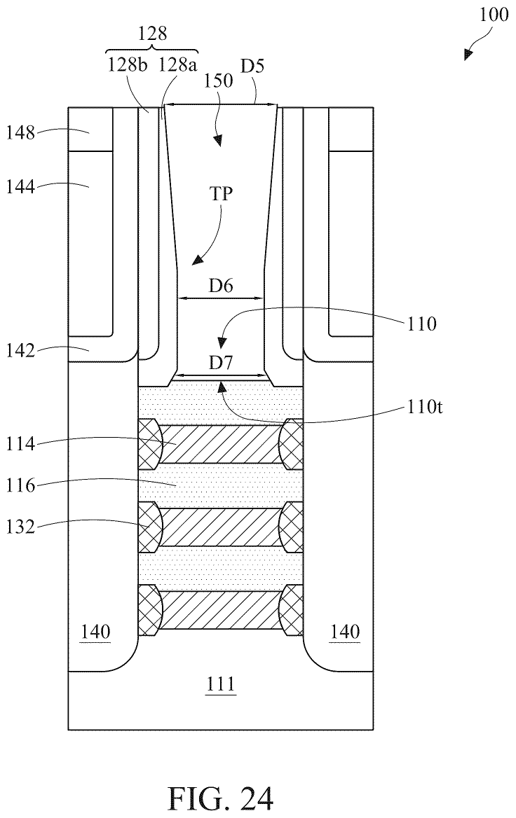

Referring to FIGS. 1 and 24, at operation 44, the method 10 removes the dummy gate dielectric layer 120m to expose the top surface 110t (as well as sidewall surfaces) of the fin 110. For example, a dry etch or a wet etch may be performed to remove the dummy gate dielectric layer 120m. In some embodiments, the dry etch may use a gas mixture of NH₃ and HF as an etchant. In some embodiments, the wet etch may use a fluorine-containing liquid, such as dHF. The etchant is selected such that the nanosheets 114 and 116 in the fin 110 is substantially intact. The capping layer 148 protects the ILD layer 144 and underneath source/drain regions 140 during removing the dummy gate dielectric layer 120m.

In the depicted embodiment as shown in FIG. 24, the top portion of the gate trench 150 has a gradually expanding width with the largest width (denoted as D5) measured at the top opening of the gate trench 150; the middle portion of the gate trench 150 has a substantially constant width (denoted as D6) such as measured at the height of the turning point TP; and the bottom portion of the gate trench 150 has a bottom width (denoted as D7) measured at the top surface 110t of the fin 110. In some embodiments, the constant width D6 may range from about 5 nm to about 200 nm, and the largest width D5 may be larger than the constant width D6 for about 0.1 nm to about 10 nm. A ratio between D5 and D6 (i.e., D5/D6) may range from about 1.01 to about 3, in some embodiments. The bottom width D7 may be larger than or smaller than the constant width D6, depending on how large the gate trench 150 is extra expanded during the cyclic process of operation 40 and operation 42. That is, in the depicted embodiment, the bottom width D7 is slightly larger than the constant width D6; yet the bottom width D7 may be smaller than the constant width D6 if the gate trench 150 has been expanded beyond the width of the dummy gate dielectric layer 120m through the cyclic processes. A ratio between D7 and D6 (i.e., D7/D6) may range from about 0.5 to about 5.

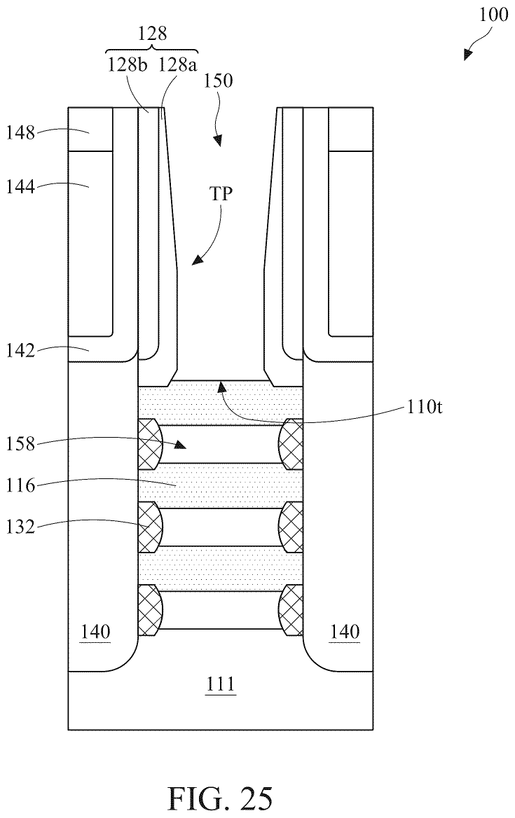

Referring to FIGS. 1 and 25, at operation 46, the method 10 performs an etching process to remove the first nanosheets 114. In the case, the first nanosheets 114 may be completely removed to form a plurality of gaps 158 between the second nanosheets 116. Accordingly, the second nanosheets 116 are separated from each other by the gaps 158. In addition, the bottommost second nanosheet 116 may also be separated from the fin base 111 by the gaps 158. As a result, the second nanosheets 116 are suspended. A height of the gaps 158 ranges from about 5 nm to about 20 nm in some embodiments. In the present embodiment, the second nanosheets 116 include silicon, and the first nanosheets 114 include silicon germanium. The first nanosheets 114 may be selectively removed by oxidizing the first nanosheets 114 using a suitable oxidizer, such as ozone. Thereafter, the oxidized first nanosheets 114 may be selectively removed from the gate trench 146. In some embodiments, the etching process includes a dry etching process to selectively remove the first nanosheets 114, for example, by applying an HCl gas at a temperature of about 20° C. to about 300° C., or applying a gas mixture of CF₄, SF₆, and CHF₃. The opposite ends of the suspended second nanosheets 116 are connected to source/drain regions 140. The suspended second nanosheet 116 may be referred to as channel members 116 hereinafter. The etching process may be referred to as channel member releasing process. The top surface 110t of the fin 110 thereon is referred to as the channel top surface 110t, which is the top surface of the topmost channel member 116.

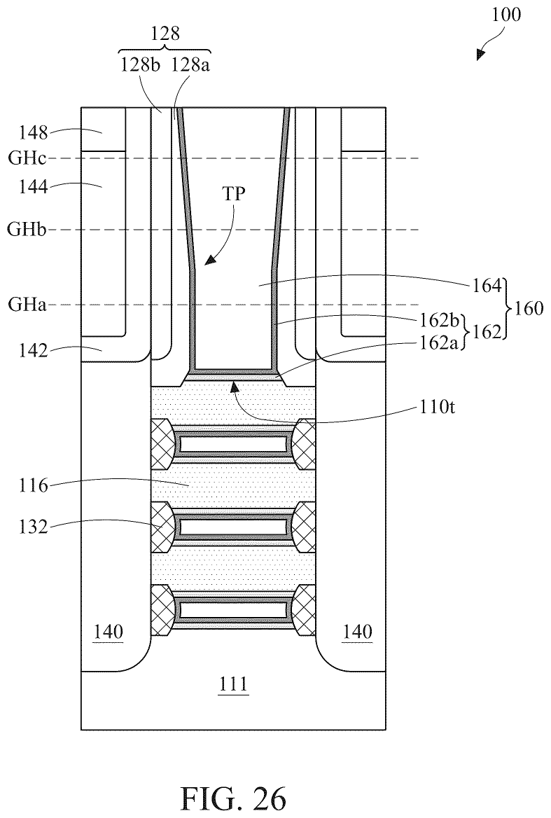

Referring to FIGS. 1 and 26, at operation 48, the method 10 forms a gate dielectric layer 162 and a gate electrode 164 in the gate trench 150 and the gaps 158. The gate electrode 164 and the gate dielectric layer 162 constitute a gate stack 160. The gate stack 160 is also referred to as the metal gate stack 160 for its metal compositions. The reshaped gate trench 150 with funnel-shape profile provides a larger opening and facilitates the deposition of various layers of the gate stack 160 into the gate trench 150. In some embodiments, the gate dielectric layer 162 includes an interfacial layer 162a formed on the surfaces of the channel members 116 and the top surface of the fin base 111, and a high-k dielectric layer 162b wrapping the interfacial layer 162a and the channel members 116 underneath. The high-k dielectric layer 162b is also disposed on opposing sidewall surfaces of the gate spacers 128 in the gate trench 146. The interfacial layer 162a is very thin and is made of, for example, SiO₂, SiOx (0<x<2), or a combination thereof. In some embodiments, the interfacial layer 162a is formed by applying an oxidizing agent on the surfaces of the channel members 116. For example, a hydrogen peroxide-containing liquid may be applied or provided on the surfaces of the channel members 116, so as to form the interfacial layer 162a. The high-k dielectric layer 162b may include a dielectric material with high dielectric constant. Examples of high-k dielectric material include HfO₂, HfSiO, HfSiON, HfTaO, HfTiO, HfZrO, zirconium oxide, lanthanum oxide, aluminum oxide, titanium oxide, hafnium dioxide-alumina (HfO₂—Al₂O₃) alloy, other suitable high-k dielectric materials, and/or combinations thereof. The high-k dielectric layer 162b may be formed by CVD, ALD or any suitable method. In one embodiment, the high-k dielectric layer 162b is formed by using a highly conformal deposition process, such as ALD in order to ensure the formation of a high-k dielectric layer having a uniform thickness around each channel member 116. A thickness of the high-k dielectric layer 162b ranges from about 0.5 nm to about 3 nm in some embodiments.

The gate electrode 164 may include various conductive materials, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. The gate electrode 164 may include one or more layers of conductive materials, such as a work function layer and a metal filling layer (not separately shown). The metal filling layer functions as a conductive filler that completely fills the remaining space of the gate trench 150.

The work function layer may be used to provide the desired work function for transistors to enhance device performance including improved threshold voltage. In some embodiments, the work function layer is used for forming a PMOS device. The work function layer is a p-type work function layer. The p-type work function layer is capable of providing a work function value suitable for the device, such as equal to or greater than about 4.8 eV. The p-type work function layer may include metal, metal carbide, metal nitride, other suitable materials, or a combination thereof. For example, the p-type metal includes tantalum nitride, tungsten nitride, titanium, titanium nitride, one or more other suitable materials, or a combination thereof. In some other embodiments, the work function layer is used for forming an NMOS device. The work function layer is an n-type work function layer. The n-type work function layer is capable of providing a work function value suitable for the device, such as equal to or less than about 4.5 eV. The n-type work function layer may include metal, metal carbide, metal nitride, or a combination thereof. For example, the n-type work function layer includes titanium nitride, tantalum, tantalum nitride, one or more other suitable materials, or a combination thereof. In some embodiments, the n-type work function layer is an aluminum-containing layer. The aluminum-containing layer may be made of or include TiAlC, TiAlO, TiAlN, one or more other suitable materials, or a combination thereof. The work function layer may also be made of or include hafnium, zirconium, titanium, tantalum, aluminum, metal carbides (e.g., hafnium carbide, zirconium carbide, titanium carbide, aluminum carbide), aluminides, ruthenium, palladium, platinum, cobalt, nickel, conductive metal oxides, or combinations thereof. The thickness and/or the compositions of the work function layer may be fine-tuned to adjust the work function level. The work function layer may be deposited over the gate dielectric layer 162 using an ALD process, a CVD process, a PVD process, an electroplating process, an electroless plating process, one or more other applicable processes, or a combination thereof.

In some embodiments, a barrier layer (not shown) is formed before the work function layer to interface the gate dielectric layer 162 with the subsequently formed work function layer. The barrier layer may also be used to prevent diffusion between the gate dielectric layer 162 and the subsequently formed work function layer. The barrier layer may be made of or include a metal-containing material. The metal-containing material may include titanium nitride, tantalum nitride, one or more other suitable materials, or a combination thereof. The barrier layer may be deposited using an ALD process, a CVD process, a PVD process, an electroplating process, an electroless plating process, one or more other applicable processes, or a combination thereof.

In some embodiments, the metal filling layer is made of or includes a metal material. The metal material may include tungsten, ruthenium, aluminum, copper, cobalt, titanium, TiN, TiAl, TiAlC, one or more other suitable materials, or a combination thereof. The metal filling layer may be deposited over the work function layer using a CVD process, an ALD process, a PVD process, an electroplating process, an electroless plating process, a spin coating process, one or more other applicable processes, or a combination thereof. In some embodiments, the metal filling layer does not extend into the gaps 158 since the gaps 158 are small and have been filled with other features such as the gate dielectric layer 162 and the work function layer. In furtherance of some embodiments, a bottom surface of the metal filling layer may be above the channel top surface 110t. However, embodiments of the disclosure are not limited thereto. In some other embodiments, a portion of the metal filling layer extends into the gaps 158 with larger space.

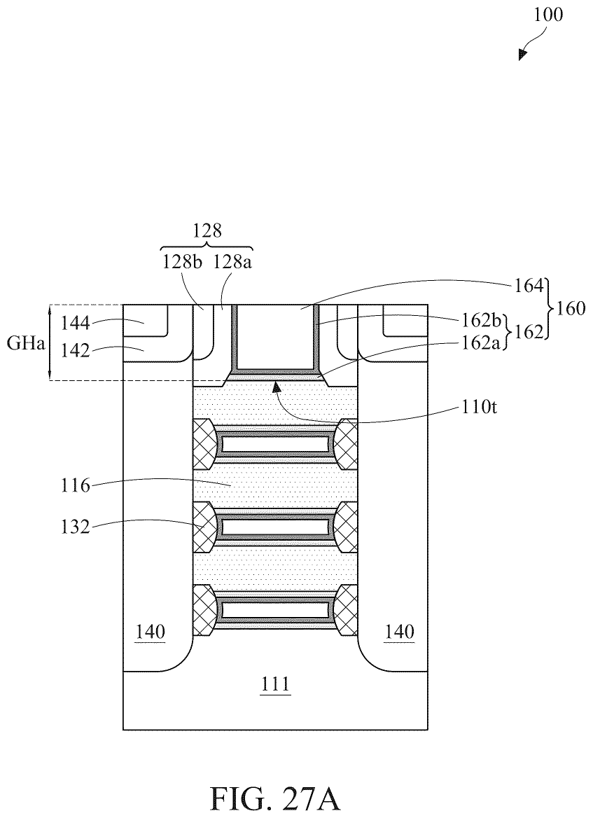

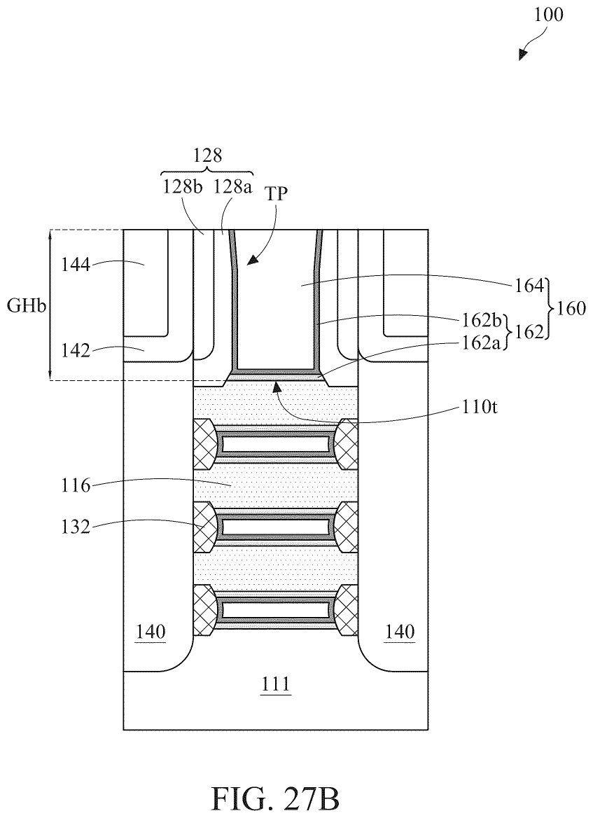

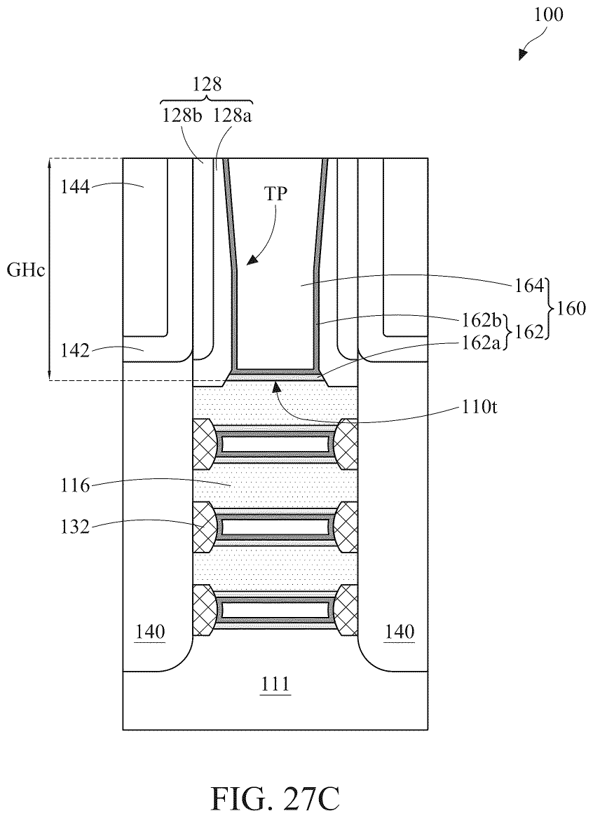

Referring to FIGS. 1 and 27A-C, at operation 50, the method 10 forms a planarization process, such as a CMP process, until the ILD layer 144 is revealed. The planarization process also recesses the gate stack 160. FIGS. 27A-C illustrate three embodiments of the resultant device 100 after operation 50. One difference is the recessed gate height (denoted as GHa, GHb, GHc, respectively) of the gate stack 160 after the planarization process. The corresponding positions of the three gate heights GHa, GHb, GHc are also marked as dotted lines in FIG. 26 for clarity. In FIG. 27A, the recessed top surface of the gate stack 160 is below the turning point TP (GHa<GH₁), such that the top portion with the tapering sidewalls is removed and the middle portion with a uniform width remains. The vertical portion of the first gate spacer layer 128a also has a substantially uniform thickness. In FIG. 27B, the recessed top surface of the gate stack 160 is above the turning point TP (GHb>GH₁), such that the top portion with the tapering sidewalls partially remains. The vertical portion of the first gate spacer layer 128a has a lower portion with a uniform thickness and an upper portion with a gradually reduced thickness. In FIG. 27C, the recessed top surface of the gate stack 160 is above the turning point TP (GHc>GH1), such that the top portion with the tapering sidewalls substantially remains. The vertical portion of the first gate spacer layer 128a has a lower portion with a uniform thickness and an upper portion with a gradually reduced thickness.

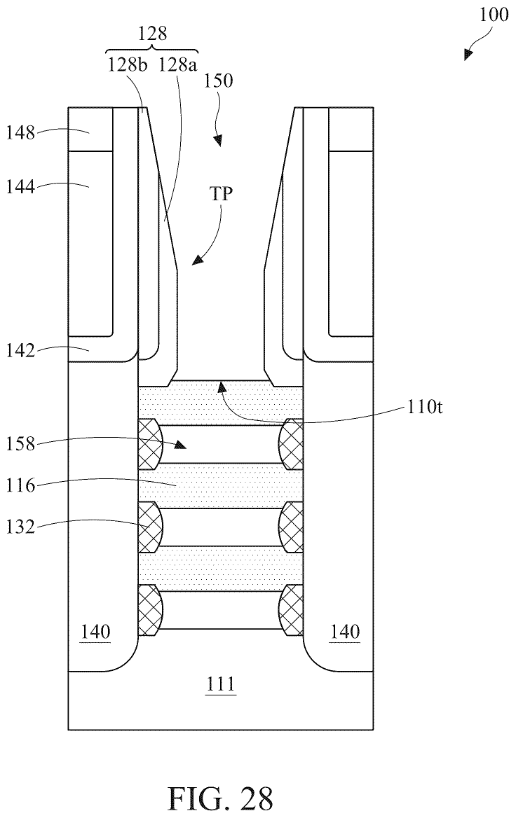

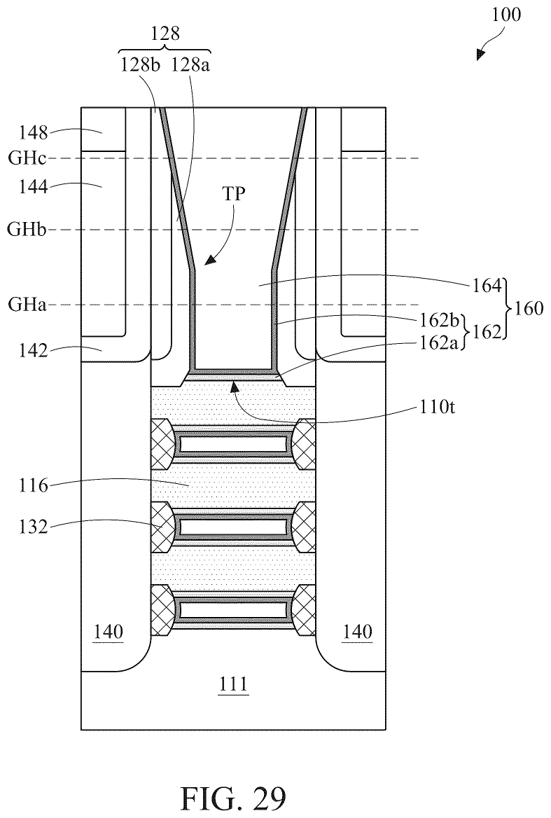

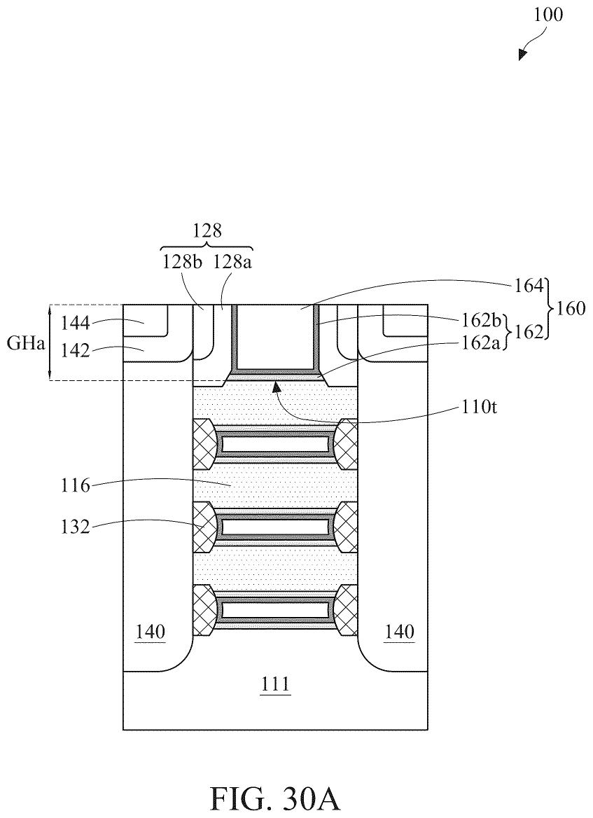

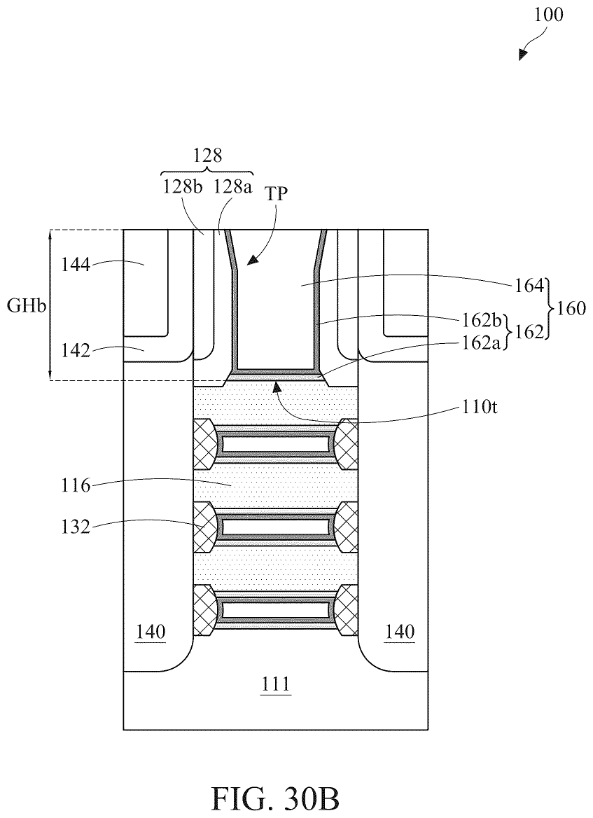

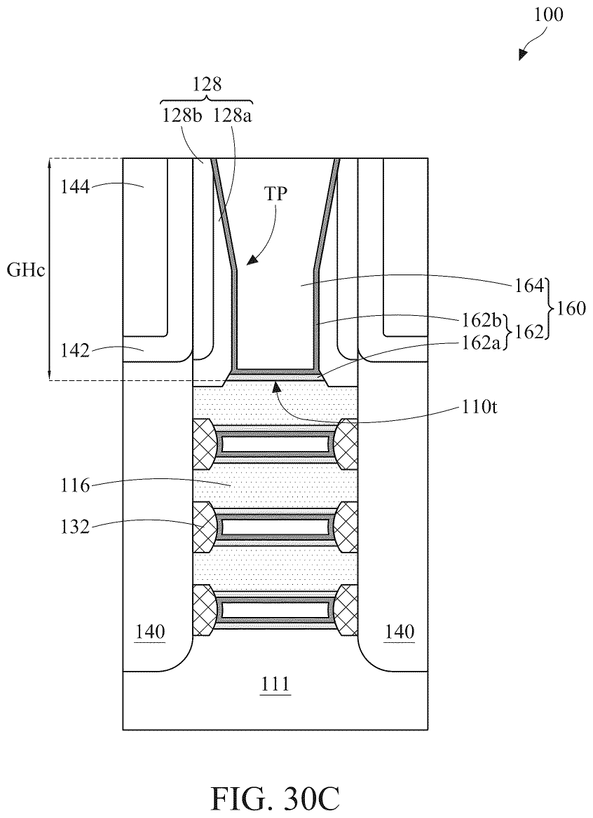

FIGS. 28, 29, and 30A-C illustrate an alternative embodiment. In FIG. 28, the gate trench reshaping expands the opening in a way such that the tapering sidewalls of the funnel-shaped profile chops a top portion of the first gate spacer layer 128a and cuts into the second gate spacer layer 128b. In FIG. 29, after the gate stack 160 is formed in the gate trench 150, the high-k dielectric layer 162b is in contact with both the first gate spacer layer 128a and the second gate spacer layer 128b. In FIG. 30A, the recessed top surface of the gate stack 160 is below the turning point TP (GHa<GH₁), such that the top portion with the tapering sidewalls is removed and the middle portion with a uniform width remains. The vertical portion of the first gate spacer layer 128a also has a substantially uniform thickness. In FIG. 30B, the recessed top surface of the gate stack 160 is above the turning point TP (GHb>GH₁), such that the top portion with the tapering sidewalls partially remains. The vertical portion of the first gate spacer layer 128a has a lower portion with a uniform thickness and an upper portion with a gradually reduced thickness. In FIG. 30C, the recessed top surface of the gate stack 160 is above the turning point TP (GHc>GH₁), such that the top portion with the tapering sidewalls substantially remains. The vertical portion of the first gate spacer layer 128a has a lower portion with a uniform thickness and an upper portion with a gradually reduced thickness. The vertical portion of the second gate spacer layer 128b has a lower portion with a uniform thickness and an upper portion with a gradually reduced thickness. The high-k dielectric layer 162b is in contact with both the first gate spacer layer 128a and the second gate spacer layer 128b.

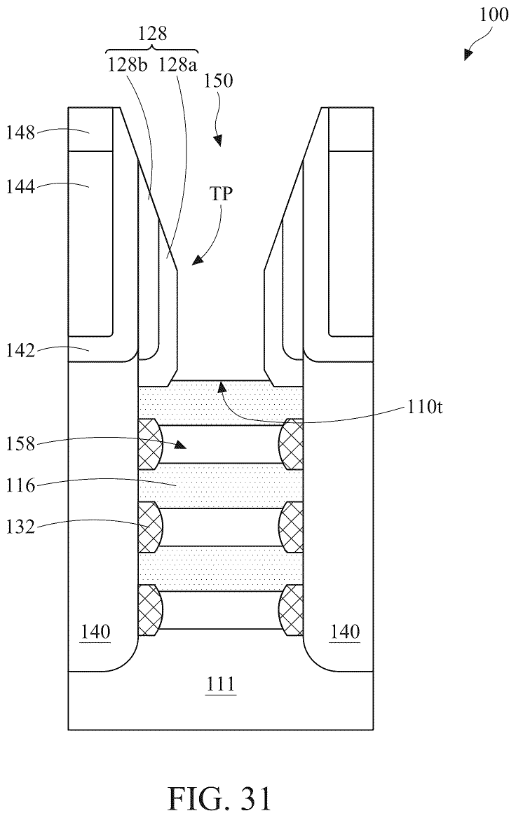

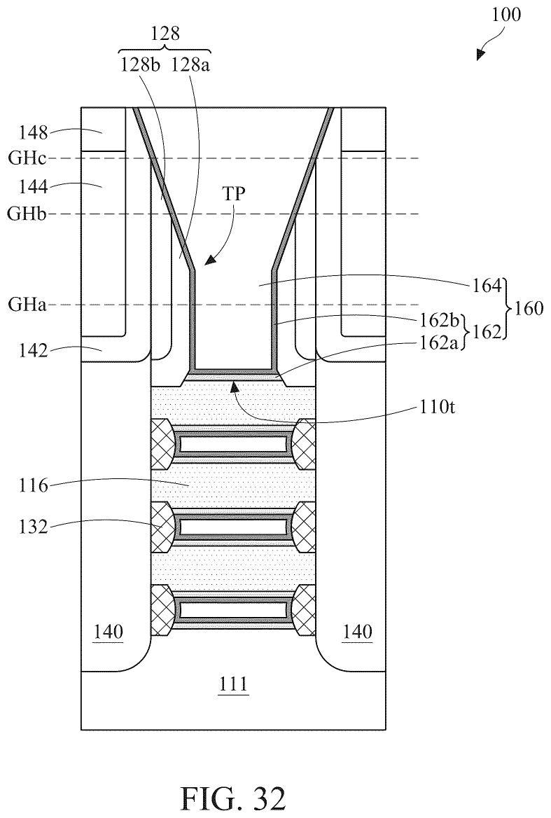

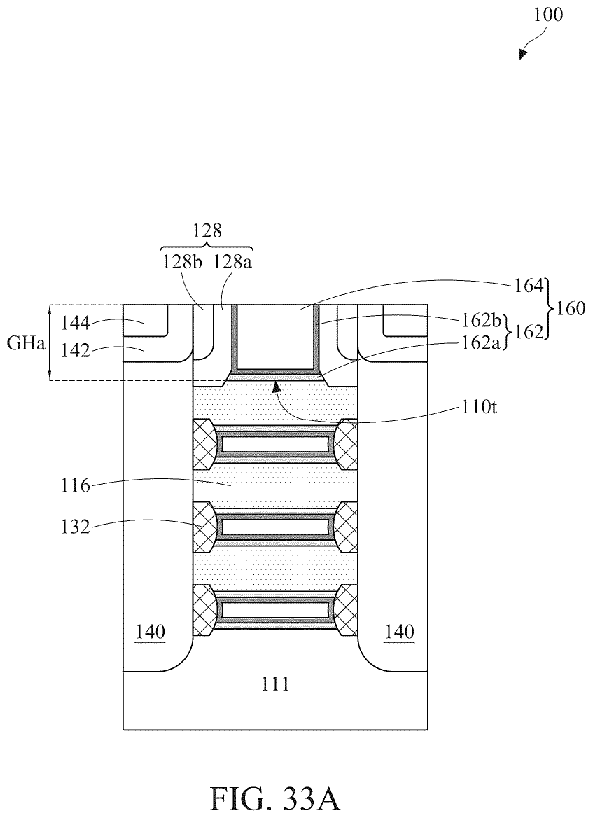

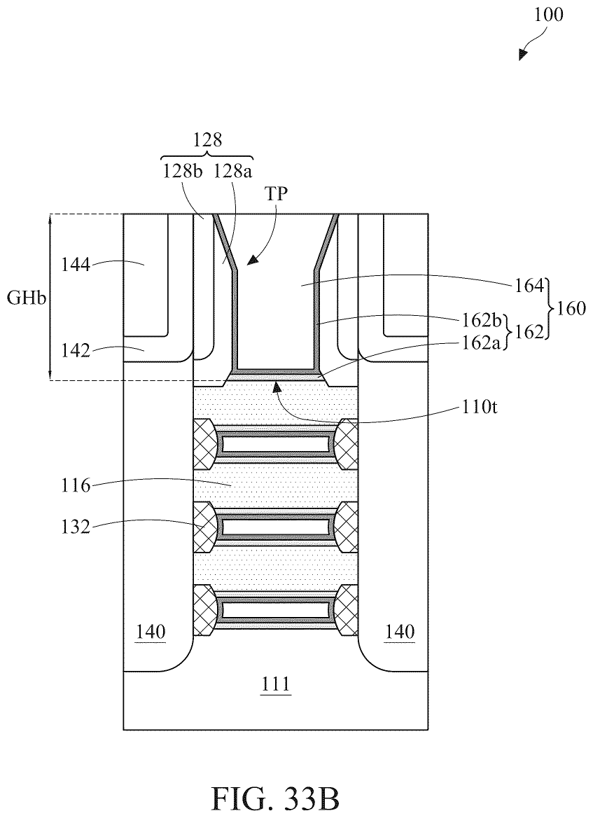

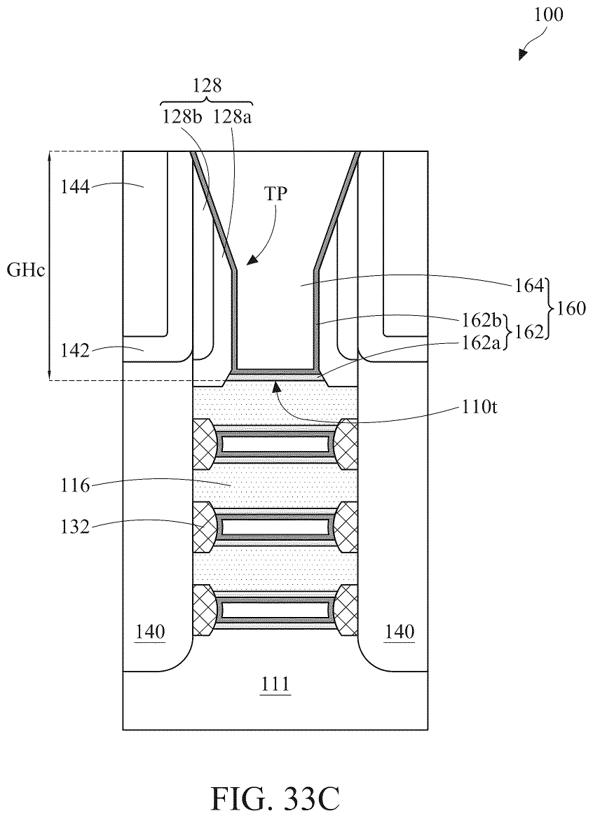

FIGS. 31, 32, and 33A-C illustrate another alternative embodiment. In FIG. 31, the gate trench reshaping expands the opening in a way such that the tapering sidewalls of the funnel-shaped profile chops a top portion of the first gate spacer layer 128a and a top portion of the second gate spacer layer 128b and further cuts into the CESL 142. In FIG. 32, after the gate stack 160 is formed in the gate trench 150, the high-k dielectric layer 162b is in contact with the first gate spacer layer 128a, the second gate spacer layer 128b, and the CESL 142. In FIG. 33A, the recessed top surface of the gate stack 160 is below the turning point TP (GHa<GH₁), such that the top portion with the tapering sidewalls is removed and the middle portion with a uniform width remains. The vertical portion of the first gate spacer layer 128a also has a substantially uniform thickness. In FIG. 33B, the recessed top surface of the gate stack 160 is above the turning point TP (GHb>GH₁), such that the top portion with the tapering sidewalls partially remains. The vertical portion of the first gate spacer layer 128a has a lower portion with a uniform thickness and an upper portion with a gradually reduced thickness. The vertical portion of the second gate spacer layer 128b has a lower portion with a uniform thickness and an upper portion with a gradually reduced thickness. The high-k dielectric layer 162b is in contact with both the first gate spacer layer 128a and the second gate spacer layer 128b. In FIG. 33C, the recessed top surface of the gate stack 160 is above the turning point TP (GHc>GH₁), such that the top portion with the tapering sidewalls substantially remains. The vertical portion of the first gate spacer layer 128a has a lower portion with a uniform thickness and an upper portion with a gradually reduced thickness. The vertical portion of the second gate spacer layer 128b has a lower portion with a uniform thickness and an upper portion with a gradually reduced thickness. The top portion of the second gate spacer layer 128b is above the top portion of the first gate spacer layer 128a. The vertical portion of CESL layer 142 has a lower portion with a uniform thickness and an upper portion with a gradually reduced thickness. The high-k dielectric layer 162b is in contact with the first gate spacer layer 128a, the second gate spacer layer 128b, and the CESL 142.

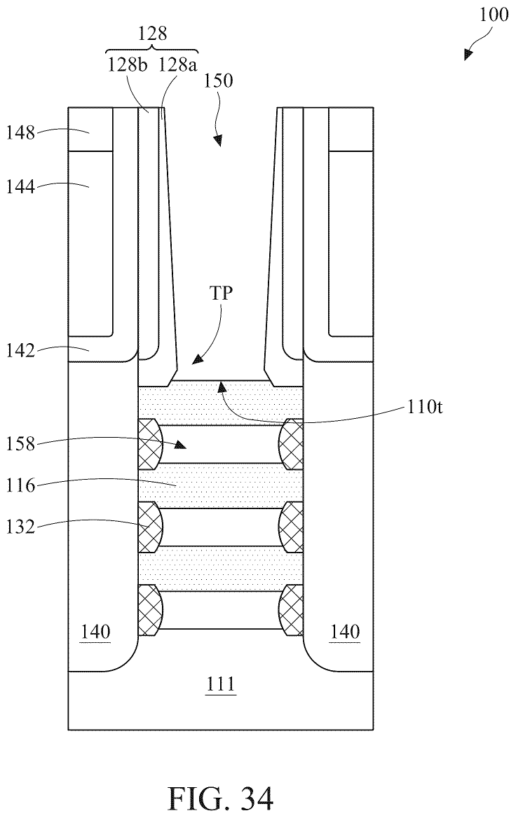

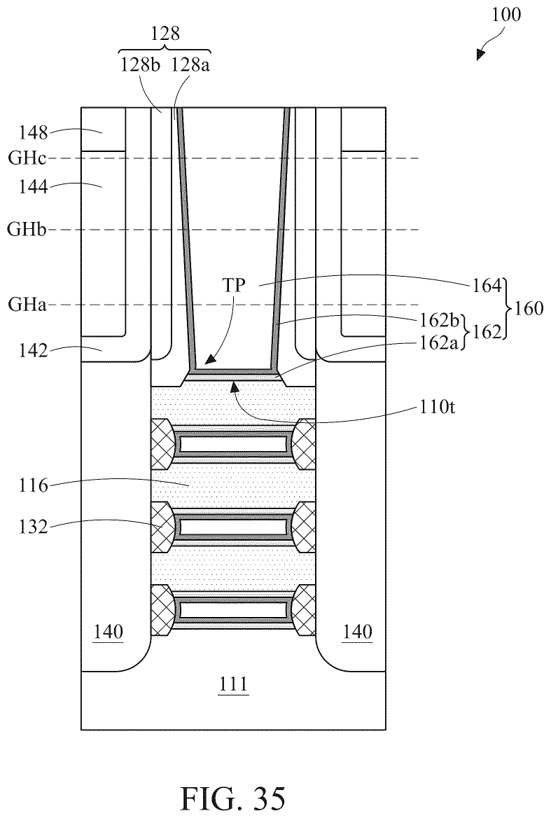

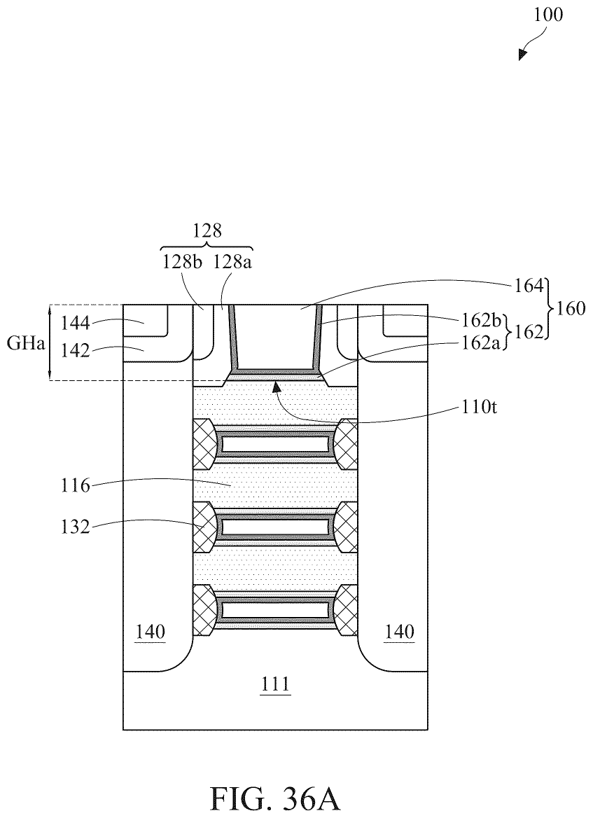

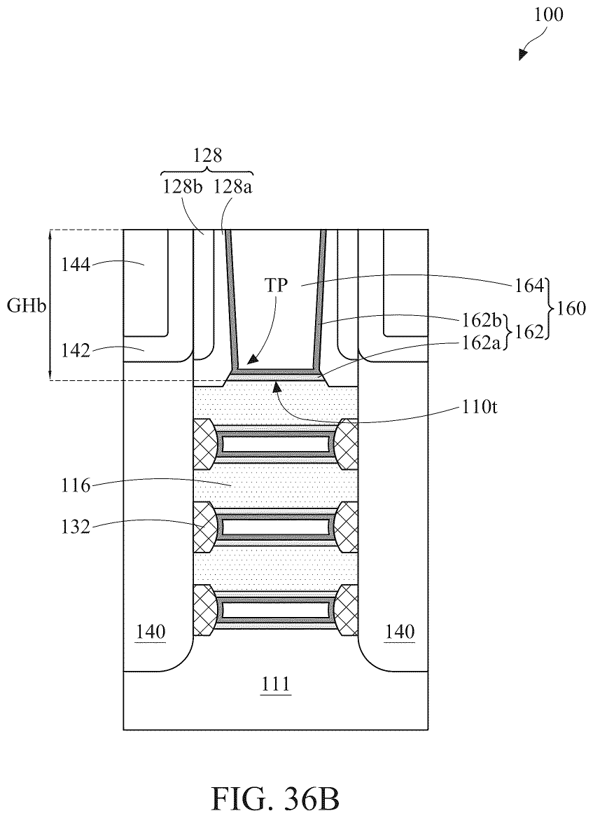

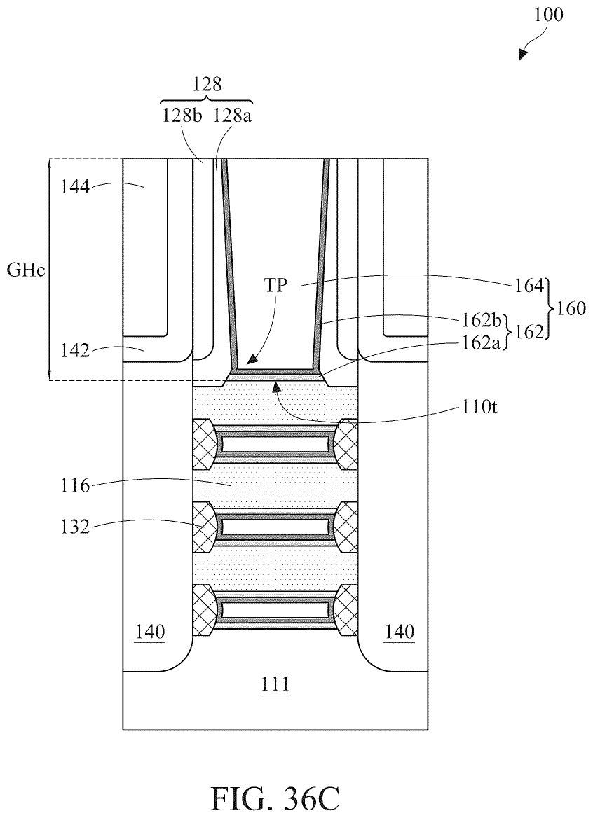

FIGS. 34, 35, and 36A-C illustrate another alternative embodiment. In FIG. 34, the gate trench reshaping sets the turning point TP at the top surface of the dummy gate dielectric layer 120m by completely etching back the oxide layer 125, such that the tapering sidewalls of the gate trench 150 start from or in proximity to the top surface of the dummy gate dielectric layer 120m. In FIG. 35, after the gate stack 160 is formed in the gate trench 150, the high-k dielectric layer 162b is in contact with the first gate spacer layer 128a. In FIG. 36A, the recessed top surface of the gate stack 160 is above the turning point TP (GHa>GH₁), the tapering sidewalls remain due to the lowering of the turning point TP, and the middle portion with a uniform width may not exist anymore due to the tapering sidewall starting from the top surface of the dummy gate dielectric layer 120m. The vertical portion of the first gate spacer layer 128a has a gradually reduced thickness. In FIG. 36B, the recessed top surface of the gate stack 160 is above the turning point TP (GHb>GH₁). The tapering sidewalls extends from the turning point TP. The vertical portion of the first gate spacer layer 128a has a gradually reduced thickness. In FIG. 36C, the recessed top surface of the gate stack 160 is above the turning point TP (GHc>GH₁). The tapering sidewalls extend from the turning point TP. The vertical portion of the first gate spacer layer 128a has a gradually reduced thickness. Although FIGS. 36A-C depict the top opening of the gate trench 250 remaining within the boundary of the first gate spacer layer 128a, the variations depicted in FIGS. 30C, 33B, and 33C may also be applied to the embodiments of FIGS. 36A-C, in which the second gate spacer layer 128b and/or the CESL 142 may also be in contact with the high-k dielectric layer 162b.

Although not intended to be limiting, one or more embodiments of the present disclosure provide many benefits to a semiconductor device and the formation thereof. For example, embodiments of the present disclosure provide a gradient passivation and etching process to enlarge a gate trench. The enlarged gate trench facilitates the subsequent material layer deposition and/or removal without leaving residues and/or trapping seams in the gate trench, which increases device performance after a gate replacement process. Further, the proposed operations in metal gate formation can be easily integrated into existing semiconductor fabrication processes.

In one exemplary aspect, the present disclosure is directed to a method of manufacturing a semiconductor device. The method includes alternately stacking first semiconductor layers and second semiconductor layers over a substrate, patterning the first and second semiconductor layers into a fin, forming a dummy gate stack across the fin, the dummy gate stack including a dummy gate dielectric layer and a dummy gate electrode over the dummy gate dielectric layer, forming a gate sidewall oxide layer over sidewalls of the dummy gate stack, depositing gate spacers over the gate sidewall oxide layer, recessing the dummy gate electrode and the gate sidewall oxide layer to form a gate trench exposing the gate spacers, passivating a top portion of the gate spacers, the passivated top portion of the gate spacers having a width reduces from top to bottom, removing the passivated top portion of the gate spacers and the gate sidewall oxide layer from the gate trench, removing the dummy gate dielectric layer from the gate trench, removing the first semiconductor layers from the gate trench to release the second semiconductor layers as channel members, and depositing a metal gate stack in the gate trench to wrap around each of the second semiconductor layers. In some embodiments, the passivating of the top portion of the gate spacers includes an oxidation process, and the passivated top portion of the gate spacers is an oxide. In some embodiments, the oxidation process is an oxygen plasma process. In some embodiments, the method further includes prior to the removing of the passivated top portion of the gate spacers and the gate sidewall oxide layer, oxidizing a layer of the gate spacers underneath the passivated top portion of the gate spacers and the gate sidewall oxide layer. In some embodiments, the oxidized layer underneath the passivated top portion of the gate spacers and the gate sidewall oxide layer has a substantially uniform width. In some embodiments, the removing of the passivated top portion of the gate spacers and the gate sidewall oxide layer includes removing the oxidized layer. In some embodiments, the method further includes after the removing of the passivated top portion of the gate spacers and the gate sidewall oxide layer, oxidizing a surface layer of the gate spacers, and removing the oxidized surface layer to expand a width of the gate trench. In some embodiments, prior to the passivating of the top portion of the gate spacers, the dummy gate electrode is fully removed. In some embodiments, the method further includes after the passivating of the top portion of the gate spacers, fully removing the dummy gate electrode. In some embodiments, the method further includes laterally recessing end portions of the first semiconductor layers, forming inner spacers on end portions of the first semiconductor layers, and forming an epitaxial feature abutting end portions of the second semiconductor layers. The inner spacers interpose the epitaxial feature and the first semiconductor layers.

In another exemplary aspect, the present disclosure is directed to a method. The method includes forming a fin protruding from a substrate, forming a dummy gate stack across the fin, the dummy gate stack including a dummy gate dielectric layer, a dummy gate electrode over the dummy gate dielectric layer, and an oxide layer disposed on sidewalls of the dummy gate electrode, forming gate spacers on sidewalls of the dummy gate stack, removing the dummy gate electrode, recessing the oxide layer to a first position vertically distant from a top surface of the fin for a first height, passivating a surface portion of the gate spacers to form a passivation layer above the oxide layer, a top portion of the passivation layer wider than a bottom portion of the passivation layer, removing the passivation layer, the oxide layer, and the dummy gate dielectric layer to form a gate trench, depositing a metal gate stack in the gate trench, and recessing the metal gate stack to a second position vertically distant from the top surface of the fin for a second height. In some embodiments, the gate trench has a largest width at an opening of the gate trench and a substantially constant width at a middle portion of the gate trench. In some embodiments, the second height is smaller than the first height. In some embodiments, the second height is larger than the first height. In some embodiments, the gate spacers include a first gate spacer layer and a second gate spacer layer, and the first gate spacer layer covers the second gate spacer layer from being in contact with the metal gate stack. In some embodiments, the gate spacers include a first gate spacer layer and a second gate spacer layer, and the first and second gate spacer layers are both in contact with the metal gate stack. In some embodiments, the method further includes extending thicknesses of the passivation layer and the oxide layer into the gate spacers.

In yet another exemplary aspect, the present disclosure is directed to a semiconductor device. The semiconductor device includes channel members vertically suspended above a substrate, a gate stack wrapping around each of the channel members, an epitaxial feature abutting the channel members, and gate spacers disposed on sidewalls of the gate stack. The gate stack has a top portion with a decreasing width in a downward direction and a middle portion with a constant width. In some embodiments, a bottom portion of the gate stack has a bottom width larger than the constant width of the middle portion. In some embodiments, the gate spacers include a first gate spacer layer and a second gate spacer layer, and the gate stack is in contact with both the first and second gate spacer layers.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
alternately stacking first semiconductor layers and second semiconductor layers over a substrate;
patterning the first and second semiconductor layers into a fin;
forming a dummy gate stack across the fin, the dummy gate stack including a dummy gate dielectric layer and a dummy gate electrode over the dummy gate dielectric layer;
forming a gate sidewall oxide layer over sidewalls of the dummy gate stack;
depositing gate spacers over the gate sidewall oxide layer;
recessing the dummy gate electrode and the gate sidewall oxide layer to form a gate trench exposing the gate spacers;
passivating a top portion of the gate spacers, the passivated top portion of the gate spacers having a width reduces from top to bottom;
removing the passivated top portion of the gate spacers and the gate sidewall oxide layer from the gate trench;
removing the dummy gate dielectric layer from the gate trench;
removing the first semiconductor layers from the gate trench to release the second semiconductor layers as channel members; and
depositing a metal gate stack in the gate trench to wrap around each of the second semiconductor layers.

2. The method of claim 1, wherein the passivating of the top portion of the gate spacers includes an oxidation process, and the passivated top portion of the gate spacers is an oxide.

3. The method of claim 2, wherein the oxidation process is an oxygen plasma process.

4. The method of claim 1, further comprising:
prior to the removing of the passivated top portion of the gate spacers and the gate sidewall oxide layer, oxidizing a layer of the gate spacers underneath the passivated top portion of the gate spacers and the gate sidewall oxide layer.

5. The method of claim 4, wherein the oxidized layer underneath the passivated top portion of the gate spacers and the gate sidewall oxide layer has a substantially uniform width.

6. The method of claim 4, wherein the removing of the passivated top portion of the gate spacers and the gate sidewall oxide layer includes removing the oxidized layer.

7. The method of claim 1, further comprising:
after the removing of the passivated top portion of the gate spacers and the gate sidewall oxide layer, oxidizing a surface layer of the gate spacers; and
removing the oxidized surface layer to expand a width of the gate trench.

8. The method of claim 1, wherein prior to the passivating of the top portion of the gate spacers, the dummy gate electrode is fully removed.

9. The method of claim 1, further comprising:
after the passivating of the top portion of the gate spacers, fully removing the dummy gate electrode.

10. The method of claim 1, further comprising:
laterally recessing end portions of the first semiconductor layers;
forming inner spacers on end portions of the first semiconductor layers; and
forming an epitaxial feature abutting end portions of the second semiconductor layers, wherein the inner spacers interpose the epitaxial feature and the first semiconductor layers.

11. A method, comprising:
forming a fin protruding from a substrate;
forming a dummy gate stack across the fin, the dummy gate stack including a dummy gate dielectric layer, a dummy gate electrode over the dummy gate dielectric layer, and an oxide layer disposed on sidewalls of the dummy gate electrode;
forming gate spacers on sidewalls of the dummy gate stack;
removing the dummy gate electrode;
recessing the oxide layer to a first position vertically distant from a top surface of the fin for a first height;
passivating a surface portion of the gate spacers to form a passivation layer above the oxide layer, a top portion of the passivation layer wider than a bottom portion of the passivation layer;
removing the passivation layer, the oxide layer, and the dummy gate dielectric layer to form a gate trench;
depositing a metal gate stack in the gate trench; and
recessing the metal gate stack to a second position vertically distant from the top surface of the fin for a second height.

12. The method of claim 11, wherein the gate trench has a largest width at an opening of the gate trench and a substantially constant width at a middle portion of the gate trench.

13. The method of claim 11, wherein the second height is smaller than the first height.

14. The method of claim 11, wherein the second height is larger than the first height.

15. The method of claim 11, wherein the gate spacers include a first gate spacer layer and a second gate spacer layer, and wherein the first gate spacer layer covers the second gate spacer layer from being in contact with the metal gate stack.

16. The method of claim 11, wherein the gate spacers include a first gate spacer layer and a second gate spacer layer, and wherein the first and second gate spacer layers are both in contact with the metal gate stack.

17. The method of claim 11, further comprising:
extending thicknesses of the passivation layer and the oxide layer into the gate spacers.

18. A semiconductor device, comprising:
channel members vertically suspended above a substrate;
a gate stack wrapping around each of the channel members;
an epitaxial feature abutting the channel members; and
gate spacers disposed on sidewalls of the gate stack,
wherein the gate stack has a top portion with a decreasing width in a downward direction and a middle portion with a constant width.

19. The semiconductor device of claim 18, wherein a bottom portion of the gate stack has a bottom width larger than the constant width of the middle portion.

20. The semiconductor device of claim 18, wherein the gate spacers include a first gate spacer layer and a second gate spacer layer, and wherein the gate stack is in contact with both the first and second gate spacer layers.
